(19) United States
(12) Patent Application Publication
(10) Pub. No.: US 2026/0198281 A1
(43) Pub. Date: Jul. 9, 2026

(54) MULTI-DIE SEMICONDUCTOR DEVICE WITH INTERFACE OR CONTROL INTERCONNECTIONS

(71) Applicant: QUALCOMM Incorporated, San Diego, CA (US)

(72) Inventors: Aniket PATIL, San Diego, CA (US); Yangyang SUN, San Diego, CA (US); Manuel ALDRETE, Encinitas, CA (US)

(21) Appl. No.: 19/013,215

(22) Filed: Jan. 8, 2025

(51) Int. Cl. H01L 23/48; H01L 23/00; H01L 23/538; H01L 25/00; H01L 25/07

(52) U.S. Cl. CPC H10W 20/20; H10W 70/611; H10W 90/00; H10W 90/401; H10W 90/297; H10W 90/722; H10W 90/724

(57) ABSTRACT

A device includes a first die and a second die. The first die includes a first set of external contacts on a first side of the first die, a first plurality of through-substrate vias (TSVs) that extend between the first side of the first die and a second side of the first die, and interface or control circuitry proximate to the first side of the first die. The second die includes a second set of external contacts on a first side of the second die, a second plurality of TSVs that extend between the first side of the second die and a second side of the second die, and processor circuitry proximate to the first side of the second die and configured to access an external resource via the interface or control circuitry.

### FIELD

Various features relate to integrated circuit devices.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

In state-of-the-art electronic devices, there is generally an expectation that integrated device packages have a small form factor, a low cost, a tight power budget, and high performance. These various goals are often in conflict. For example, high speed memory devices often utilize one or more protocols for communication between a processor and the memory device, as managed by a controller. Some packaged semiconductor devices that include both a processor die and a memory die are designed such that a controller (within the processor die) is located approximately at the center of the package such that the controller is near to other components such as a central processing unit (CPU), a graphics processing unit (GPU), and/or a modem that are associated with tight latency criteria. The controller is also connected through channels to protocol interface (IF) circuitry to enable the controller to communicate with the memory die using a particular protocol. The protocol IF circuitry is typically located near the edge of the package so that the contacts may fan out and connect to input/output (I/O) ports of the memory die. These channels act as memory pipeline(s) that travel from the edge of the package to the center. As packaged semiconductor devices become more complex, the increased complexity results in larger package sizes and thus longer pipelines, which can increase delay for multi-die memory devices.

### SUMMARY

Various features relate to integrated circuit devices.

One example provides a device that includes a first die and a second die. The first die includes a first set of external contacts on a first side of the first die, a first plurality of through-substrate vias (TSVs) that extend between the first side of the first die and a second side of the first die, and interface or control circuitry proximate to the first side of the first die. The second die includes a second set of external contacts on a first side of the second die, a second plurality of TSVs that extend between the first side of the second die and a second side of the second die, and processor circuitry proximate to the first side of the second die and configured to access an external resource via the interface or control circuitry.

Another example provides a method of semiconductor fabrication that includes obtaining a first die coupled to an interposer. The first die includes a first set of external contacts on a first side of the first die and electrically coupled to the interposer. The first die also includes a first plurality of TSVs that extend between the first side of the first die and a second side of the first die. The first die also includes interface or control circuitry proximate to the first side of the first die. The method also includes electrically coupling a second die to the first die. The second die includes a second set of external contacts on a first side of the second die. The second die also includes a second plurality of TSVs that extend between the first side of the second die and a second side of the second die. The second die also includes processor circuitry proximate to the first side of the second die and configured to access an external resource via the interface or control circuitry.

Another example provides a method of semiconductor fabrication that includes obtaining an assembly that includes a first die coupled to a second die. The first die includes a first set of external contacts on a first side of the first die. The first die also includes a first plurality of TSVs that extend between the first side of the first die and a second side of the first die. The first die also includes interface or control circuitry proximate to the first side of the first die. The second die includes a second set of external contacts on a first side of the second die. The second die also includes a second plurality of TSVs that extend between the first side of the second die and a second side of the second die. The second die also includes processor circuitry proximate to the first side of the second die and configured to access an external resource via the interface or control circuitry. The method also includes electrically coupling the second set of external contacts to a substrate.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross-sectional profile view of an exemplary device that includes interface or control interconnections for an external resource.

FIG. 2 illustrates a cross-sectional profile view of a particular implementation of a packaged semiconductor device that includes interface or control interconnections between multiple dies.

FIG. 3A illustrates a first part of an exemplary sequence for fabricating an exemplary device that includes interface or control interconnections between multiple dies.

FIG. 3B illustrates a second part of an exemplary sequence for fabricating an exemplary device that includes interface or control interconnections between multiple dies.

FIG. 3C illustrates a third part of an exemplary sequence for fabricating an exemplary device that includes interface or control interconnections between multiple dies.

FIG. 3D illustrates a fourth part of an exemplary sequence for fabricating an exemplary device that includes interface or control interconnections between multiple dies.

FIG. 3E illustrates a fifth part of an exemplary sequence for fabricating an exemplary device that includes interface or control interconnections between multiple dies.

FIG. 3F illustrates a sixth part of an exemplary sequence for fabricating an exemplary device that includes interface or control interconnections between multiple dies.

FIG. 4A illustrates a first part of another exemplary sequence for fabricating an exemplary device that includes interface or control interconnections between multiple dies.

FIG. 4B illustrates a second part of another exemplary sequence for fabricating an exemplary device that includes interface or control interconnections between multiple dies.

FIG. 4C illustrates a third part of another exemplary sequence for fabricating an exemplary device that includes interface or control interconnections between multiple dies.

FIG. 5 illustrates an exemplary flow diagram of a method of semiconductor fabrication for a device that includes interface or control interconnections between multiple dies.

FIG. 6 illustrates an exemplary flow diagram of another method of semiconductor fabrication for a device that includes interface or control interconnections between multiple dies.

FIG. 7 illustrates various electronic devices that may integrate an exemplary packaged semiconductor device that includes interface or control interconnections between multiple dies described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art device.

These interconnections include back-end-of-line (BEOL) interconnect layers, which may refer to the conductive interconnect layers for electrically coupling to front end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middleof-line (MOL) interconnect layers, which interconnect to the FEOL active devices of an IC.

State-of-the-art electronic devices (e.g., portable computing devices, mobile communication devices, wearable devices, special purpose computing devices, etc.) demand a small form factor, low cost, a tight power budget, and high electrical performance. Integrated circuit package design has evolved to meet these divergent goals. One approach to reducing package size is to integrate multiple dies within a single package. One example of a multi-die package is a two-dimensional (2D) package architecture, in which two or more dies are coupled to a package substrate side-by-side with one another. Dies in this configuration can interact with one another (e.g., via die-to-die connections) and with off-package devices (e.g., via off-package connections). A challenge of such configurations is that die-to-die and off-package connections have different design criteria. For example, off-package connections are generally larger (e.g., in terms of line width, line spacing, etc.) than is needed for die-to-die connections. Various workarounds have been used to address this size difference. For example, additional devices (e.g., interposer devices or bridge die) can be added to a package to route die-to-die connections using smaller lines. As another example, additional layers or a separate stacked substrate can be added to the package substrate to provide die-to-die connection and redistribution routing to connect to off-package connections.

Another approach to reducing package size is a 2.5D architecture, in which two or more devices are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. Stacked die schemes and chiplet architectures are becoming more common as significant power performance area (PPA) yield enhancements are demonstrated for stacked die and chiplet architecture product lines.

Aspects of the present disclosure are directed to integrated devices that include interface or control interconnections between dies. In some aspects, a packaged semiconductor device includes multiple dies that are coupled together and configured to enable access by processor circuitry of one die to an external resource, such as a third die (e.g., a dynamic random-access memory (DRAM) die). For example, a first die may include a first set of external contacts on a first side of the first die, a first plurality of through-substrate vias (TSVs) that extend between the first side of the first die and a second side of the first die, and interface or control circuitry proximate to the first side of the first die. The second die, which is coupled in a back-to-back configuration with the first die, may include a second set of external contacts on a first side of the second die, a second plurality of TSVs that extend between the first side of the second die and a second side of the second die, and processor circuitry proximate to the first side of the second die and configured to access an external resource via the interface or control circuitry.

In such embodiments, the first die includes interface (IF) circuitry, and optionally controller(s), that would typically be implemented as part of the processor circuitry and configured to communicate with an external resource via one or more protocols. This circuitry is offloaded to a separate die that is stacked on top of the processor die (e.g., a system on chip (SoC)) and that is interconnected with the other die by the TSVs. The TSVs through both dies provide connections for the SoC to an external resource, such as a DRAM die, that is managed by the IF circuitry. Because the distance of the TSVs is less than typical memory channels that are routed between IF circuitry on the edge of a package and an SoC in the center of the package, the delay is reduced compared to other devices. As such, the disclosed device with the interface or control interconnects (e.g., the TSVs that extend through the two dies) provides a multi-die memory device with less delay and a smaller package size than other multi-die memory devices.

### Exemplary Device Including Interface or Control Interconnections Between Dies

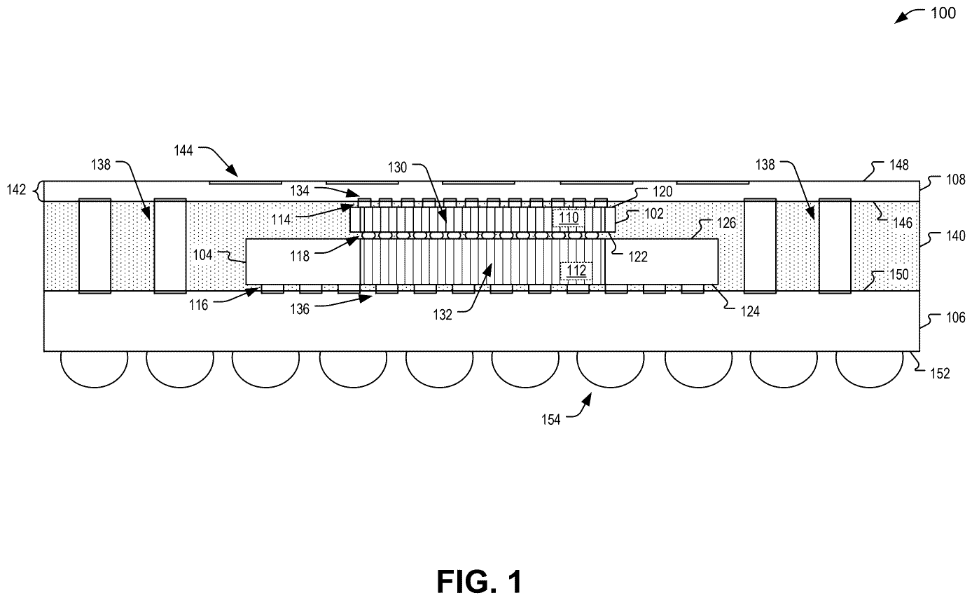

FIG. 1 illustrates a cross-sectional profile view of an exemplary device 100 that includes interface or control interconnections for an external resource. In the implementation shown in FIG. 1, the device 100 includes a first die 102, a second die 104, a substrate 106, and an interposer 108. The first die 102 and the second die 104 are disposed between the substrate 106 and the interposer 108 and are arranged in a “back-to-back” configuration such that the first die 102 faces a first direction that is opposite to a second direction faced by the second die 104, as further described below.

Each of the dies 102, 104 can include integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate.

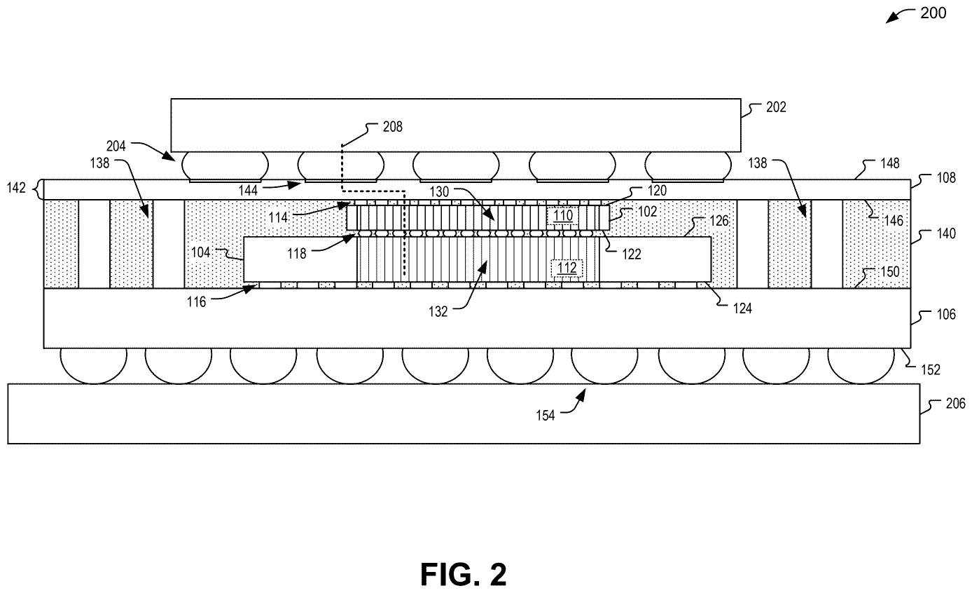

The dies 102, 104 may include or correspond to particular integrated circuit (IC) devices that can be arranged and interconnected as a three-dimensional (3D) IC device or a 2.5D IC device. In some implementations, the dies 102, 104 include one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the dies 102, 104. Additionally, or alternatively, the dies 102, 104 may include or be operated as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof. In some specific embodiments, the second die 104 includes processor circuitry 112, such as an SoC, and the first die 102 includes interface or control circuitry 110. If the processor circuitry 112 includes or corresponds to an SoC, the processor circuitry 112 may be an IC that includes some or all of the components of a computer system, such as an on-chip CPU, input/output (I/O) interfaces, memory interfaces that are not included in the interface or control circuitry 110, and in some implementations, one or more modems or graphic processing units (GPUs). The interface or control circuitry 110 included in the first die 102 may be configured to enable access by the processor circuitry 112 of the first die 102 to an external resource, such as a DRAM die, as further described herein with reference to FIG. 2.

The interface or control circuitry 110 may include interface (IF) circuitry, one or more controllers, or a combination thereof. The IF circuitry can include one or more passive circuit elements, such as capacitors, inductors, filters, or the like, that are configured to transform signals from a first protocol used by the SoC (e.g., the second die 104) to a second protocol used by an external resource (e.g., a DRAM or another die), or vice versa. In some examples, the IF circuitry can also include active circuit element(s). Additionally, or alternatively, the interface or control circuitry 110 can include interface circuitry (e.g., a serializer/deserializer (SerDes), a memory bus interface circuit, etc.), memory buffers, and/or other circuitry that facilitates interaction between the second die 104 and the external resource.

In a particular embodiment, the external resource is a double data rate (DDR) memory, the interface or control circuitry 110 may include a DDR-type DRAM bus interface or other DDR interface circuitry, and the interface or control circuitry 110 is configured to convert signals between a DDR protocol used by the DDR memory and a physical interface (PHY) protocol used by the IF circuitry and the processor circuitry 112 of the second die 104. In some such embodiments, the interface or control circuitry 110 represents a dedicated small die that includes DDR PHY circuitry, memory controller, or both, that are effectively “split off” from the parent logic SoC (e.g., the processor circuitry 112). In other embodiments, the external resource can be a different type of IC die, and the interface or control circuitry 110 may be configured to convert signaling between a different device-specific protocol and the PHY protocol (or another protocol). As a non-limiting example, the external resource may be a Universal Flash Storage (UFS) die, and the interface or control circuitry 110 may be configured to convert signals between a UFS protocol used by the IF circuitry and the processor circuitry 112 of the second die 104.

In addition to the interface or control circuitry 110, the first die 102 also includes external contacts 114 (e.g., a first set of external contacts) on a first side 120 of the first die 102. The external contacts 114 may be configured to be coupled to an external resource, such as a memory die, that is external to the device 100 and thus are referred to as “external” contacts. For example, the external contacts 114 may be coupled (via one or more intervening elements or layers) to one or more off-package contacts configured to be coupled to the external resource, as further described herein. In some embodiments, the external contacts 114 include or correspond to bump pads or contact pads. In other embodiments, the external contacts 114 include or correspond to different types of external contacts. Any of the electrical interconnects and contacts described herein can include, for example, microbumps, conductive pillars, conductive pads (e.g., for pad-to-pad bonding), or other similar chiplet-to-chiplet interconnect contacts used for 3D-chiplet stacking. Additionally, or alternatively, the electrical interconnects, contacts, and conductors described herein can include, for example, solder balls, solder paste, solder structures, ball-grid array (BGA) balls, or other similar off-package contacts used for 3D or 2.5D package stacking.

The first die 102 also includes first through-substrate vias (TSVs) 130 (e.g., a first plurality of TSVs) that extend between the first side 120 of the first die 102 and a second side 122 of the first die 102. For example, the first die 102 may be manufactured with multiple TSVs (e.g., the first TSVs 130) that provide electrical connections between the first side 120 and the second side 122. In at least some embodiments, the first TSVs 130 include or correspond to through-silicon vias as the first die 102 includes or corresponds to a silicon die. The first TSVs 130 may extend from the second side 122 of the first die 102 to one or more layers at or near the first side 120 of the first die 102, and thus be between the first side 120 and the second side 122. For example, the first TSVs 130 may extend from the back (e.g., the second side 122) to a metal layer on front of the first die 102 that has one or more metal layers on top (e.g., for redistribution routing). As another example, the first TSVs 130 may extend from the second side 122 to the first side 120 (e.g., from the opposite external metal layers of the first die 102). The first TSVs 130 may support connections between circuitry at or connected to the first side 120 of the first die 102 and circuitry at or connected to the second side 122 of the first die 102. For example, the interface or control circuitry 110 may be proximate to the first side 120 of the first die 102, and the first TSVs 130 may facilitate a communicative coupling between the interface or control circuitry 110 and circuitry coupled to the second side 122 of the first die 102, as further described below.

In addition to the processor circuitry 112, the second die 104 also includes external contacts 116 (e.g., a second set of external contacts) on a first side 124 of the second die 104. The external contacts 116 may be configured to be coupled to an external resource, such as a printed circuit board or another resource that is external to the package of the device 100 (e.g., and that may be located within another packaged semiconductor device), and thus are referred to as “external” contacts. For example, the external contacts 116 may be coupled (via one or more intervening elements or layers) to one or more off-package contacts configured to be coupled to an off-package device or resource, as further described herein. In some embodiments, the external contacts 116 include or correspond to bump pads or contact pads, or any other type of contacts described herein that facilitate an external or off-package connection.

The second die 104 also includes second TSVs 132 (e.g., a second plurality of TSVs) that extend between the first side 124 of the second die 104 and a second side 126 of the second die 104. For example, the second die 104 may be manufactured with multiple TSVs (e.g., the second TSVs 132) that provide electrical connections between the first side 124 and the second side 126. In at least some embodiments, the second TSVs 132 include or correspond to through-silicon vias as the second die 104 includes or corresponds to a silicon die. The second TSVs 132 may extend from the second side 126 of the second die 104 to one or more layers at or near the first side 124 of the second die 104, and thus be between the first side 124 and the second side 126. For example, the second TSVs 132 may extend from the back (e.g., the second side 126) to a metal layer on front of the second die 104 that has one or more metal layers on top (e.g., for redistribution routing). As another example, the second TSVs 132 may extend from the second side 126 to the first side 124 (e.g., from the opposite external metal layers of the second die 104). The second TSVs 132 may support connections between circuitry at or connected to the first side 124 of the second die 104 and circuitry at or connected to the second side 126 of the second die 104. For example, the processor circuitry 112 may be proximate to the first side 124 of the second die 104, and the second TSVs 132 may facilitate a communicative coupling between the processor circuitry 112 and circuitry coupled to the second side 126 of the second die 104, as further described below.

As shown in FIG. 1, the first die 102 is attached to the second die 104. For example, the second side 122 of the first die 102 may be electrically coupled to the second side 126 of the second die 104. To illustrate, in an embodiment in which the first die 102 is a DDR PHY and controller die and the second die 104 is a SoC die, the bottom die (e.g., the SoC die) has bumps (e.g., the external contacts 116) that face down and the top die (e.g., the DDR PHY and controller die) has bumps (e.g., the external contacts 114) that face up, in the orientation shown in FIG. 1. Such a configuration may be referred to as the dies 102, 104 being coupled “back to back” or in a “back to back” arrangement, the first sides 120, 124 may be referred to as the front faces of the dies 102, 104, respectively, and the second sides 122, 126 may be referred to as the back faces of the dies 102, 104, respectively.

The dies 102, 104 may be attached together as shown in FIG. 1 using a die attach process, such as a metal-to-metal or hybrid attachment process. For example, the first die 102 may be attached to the second die 104 by forming joints 118 between the first die 102 and the second die 104. The joints 118 may be metal joints that are soldered or hybrid bonded to the first TSVs 130 and the second TSVs 132, and the dies 102, 104 may be attached using microbump reflow or hybrid bonding, such as copper (Cu) to Cu bonding. The joints 118 may connect TSVs in each of the dies 102, 104 as pairs of TSVs that form interconnects between the first die 102 and the second die 104. For example, the first TSVs 130 and the second TSVs 132 are arranged to form interconnected TSV pairs that extend between the first side 120 of the first die 102 and the first side 124 of the second die 104. Such interconnects may form signal paths between the interface or control circuitry 110 and the processor circuitry 112. To illustrate, a first signal path from the interface or control circuitry 110 to the processor circuitry 112 may include a first TSV of the first TSVs 130 and a second TSV of the second TSVs 132 that is coupled to the first TSV (e.g., via one of the joints 118). The interconnections formed by the pairs of TSVs through each of the dies 102, 104 replace the memory pipeline channels (e.g., communication channels) of conventional packaged semiconductor devices. Because the combined thickness of the first die 102 and the second die 104 may be less than the width of the second die 104, the length of the interconnects between the first die 102 and the second die 104 (e.g., respective TSV pairs of the first TSVs 130 and the second TSVs 132) may be shorter than the memory pipeline channels of conventional semiconductor package devices.

The interposer 108 includes on-package contacts 134 (e.g., a first set of on-package contacts) and off-package contacts 144 (e.g., a first set of off-package contacts). For example, the on-package contacts 134 may be on a first side 146 (e.g., a bottom side, or a front side with respect to the device 100) of the interposer 108 and the off-package contacts 144 may be on a second side 148 (e.g., a top side, or a back side with respect to the device 100) of the interposer 108 that is opposite from the first side 146. An external resource, such as a DRAM die, may be coupled to the off-package contacts 144, as further described herein with reference to FIG. 2. The interposer 108 also includes redistribution layers 142 (e.g., a first set of redistribution layers) coupled to the first side 120 (e.g., the front side or face) of the first die 102. For example, a portion of the on-package contacts 134 of the interposer 108 may be electrically coupled to the external contacts 114 of the first die 102, such that at least a portion of the first side 146 of the interposer 108 is coupled to the first side 120 of the first die 102.

The redistribution layers 142 define conductive paths between one or more of the on-package contacts 134 and the off-package contacts 144. Conductors of the redistribution layers 142 can use finer line width, closer line spacing, or both, as compared to conductors of a package substrate. As a result, less space can be used to route conductive paths through the redistribution layers 142 than would be needed if the same number and arrangement of interconnects were routed through a package substrate. Thus, the interposer 108 can be smaller (in terms of lateral dimension, thickness, or both) than a corresponding laminate interposer. In some embodiments, the redistribution layers 142 include two or three redistribution layers that have a minimal thermal impact on the device 100.

The substrate 106 includes on-package contacts 136 (e.g., a second set of on-package contacts) and a set of pads (not shown). For example, the on-package contacts 136 may be on a first side 150 (e.g., a top side, or a back side with respect to the device 100) of the substrate 106, and the set of pads may be on a second side 152 (e.g., a bottom side, or a front side with respect to the device 100) of the substrate 106 that is opposite from the first side 150. The set of pads may be coupled to off-package contacts 154 (e.g., a second set of off-package contacts). The off-package contacts 154 may include or correspond to BGA balls or other contacts or structures configured to be coupled to an external resource. One or more external resources, such as other packaged semiconductor devices, may be coupled to the device 100 by coupling the off-package contacts 154 to a printed circuit board (PCB), as further described herein with reference to FIG. 2. The 3D IC assembly formed by the first die 102 and the second die 104 may be placed on and coupled to the substrate 106, such that the substrate 106 acts as a package substrate for the device 100 and the off-package contacts 154 are configured to be coupled to another package or a PCB. For example, a portion of the on-package contacts 136 of the substrate 106 may be coupled to the external contacts 116 of the second die 104, such that at least a portion of the first side 150 of the substrate 106 is coupled to the first side 124 of the second die 104.

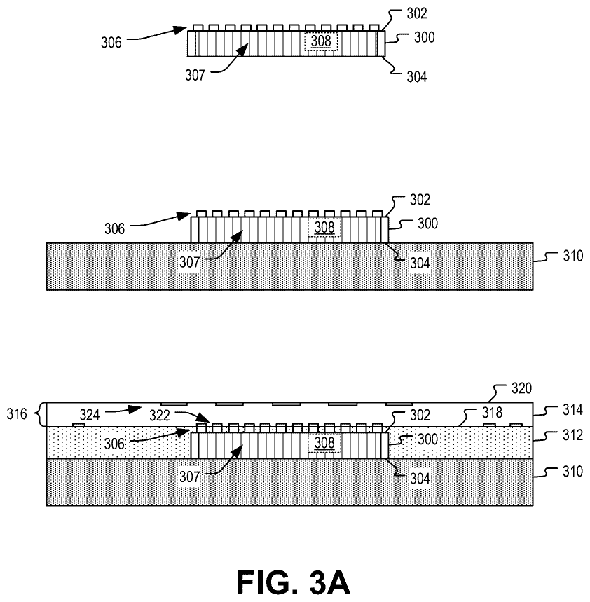

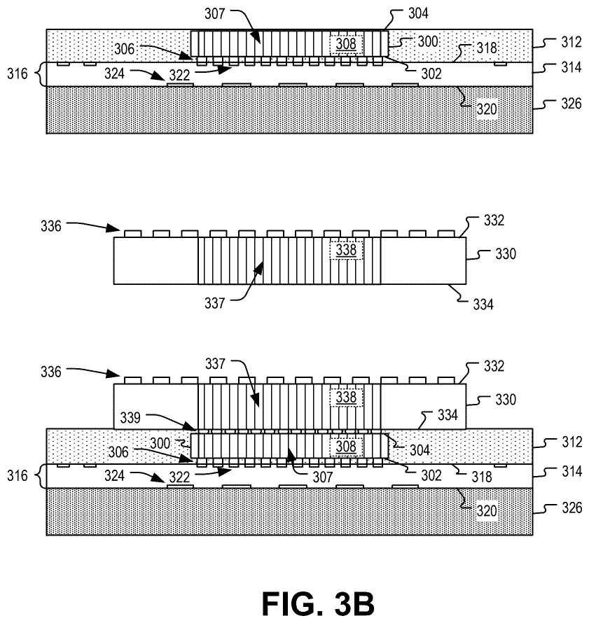

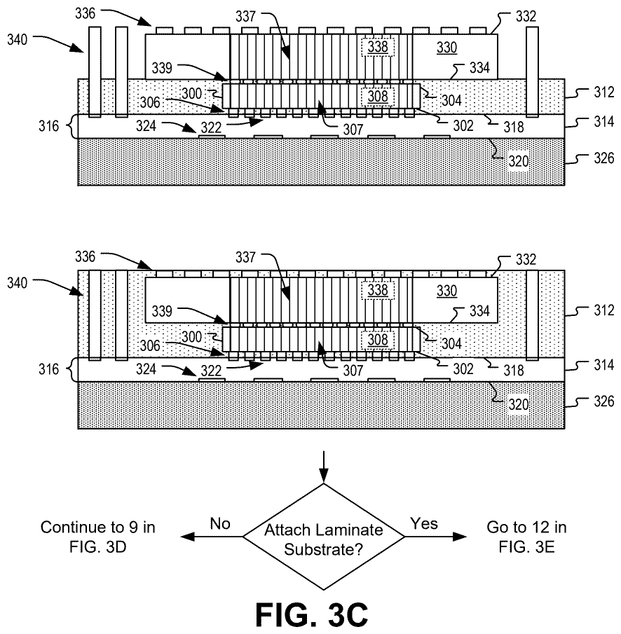

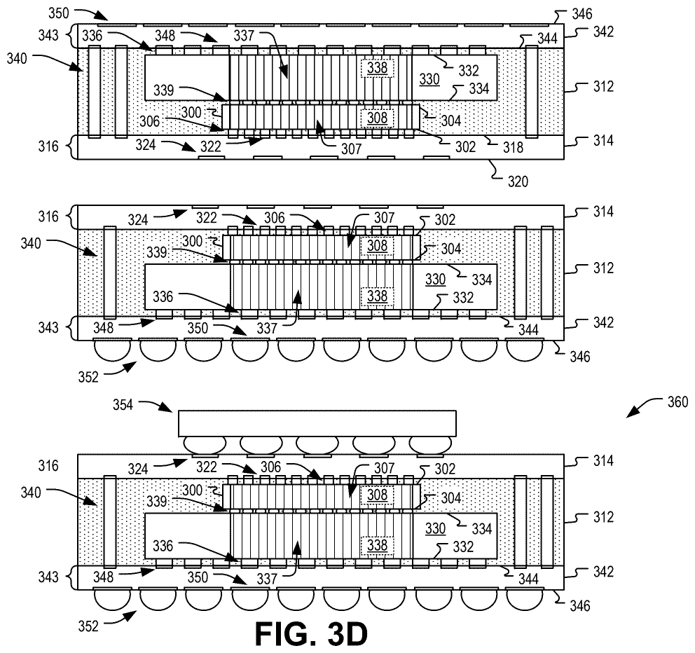

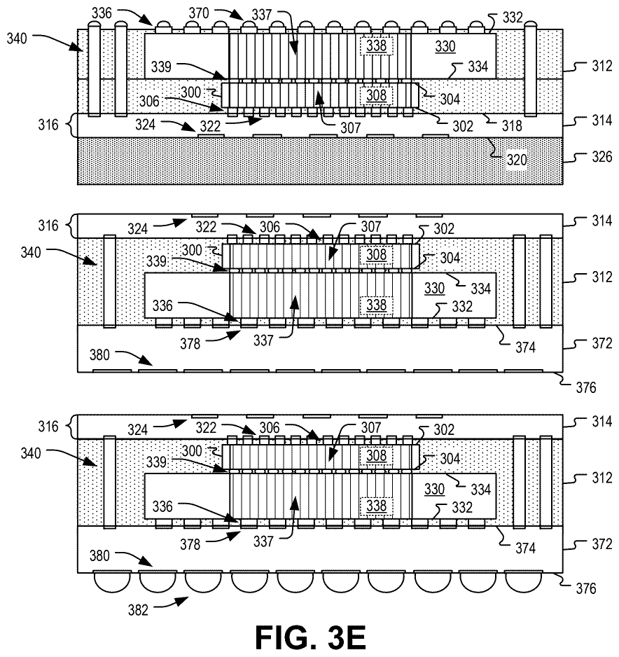

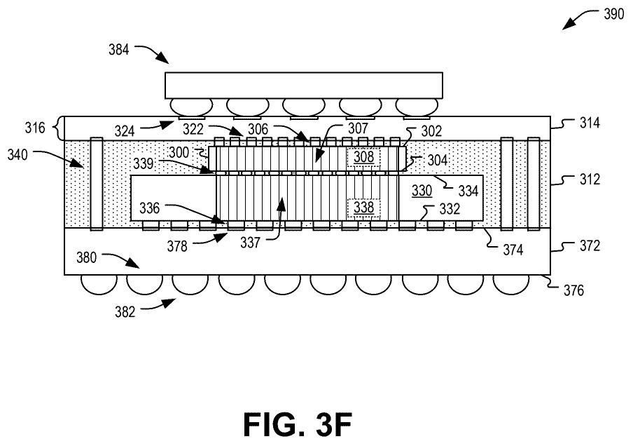

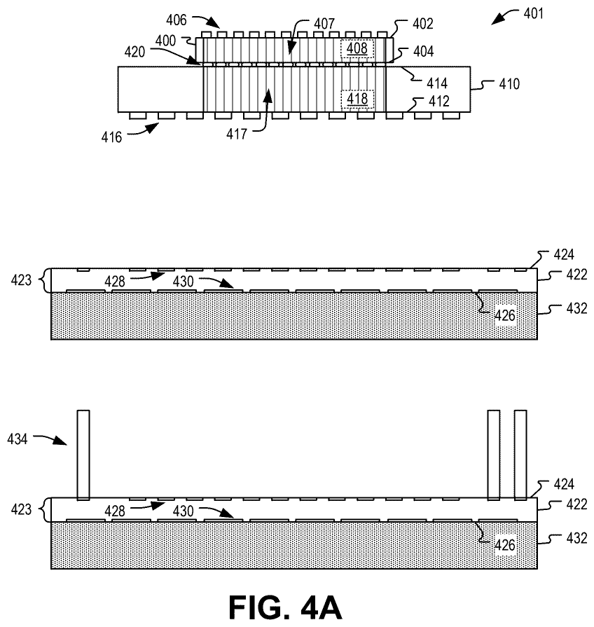

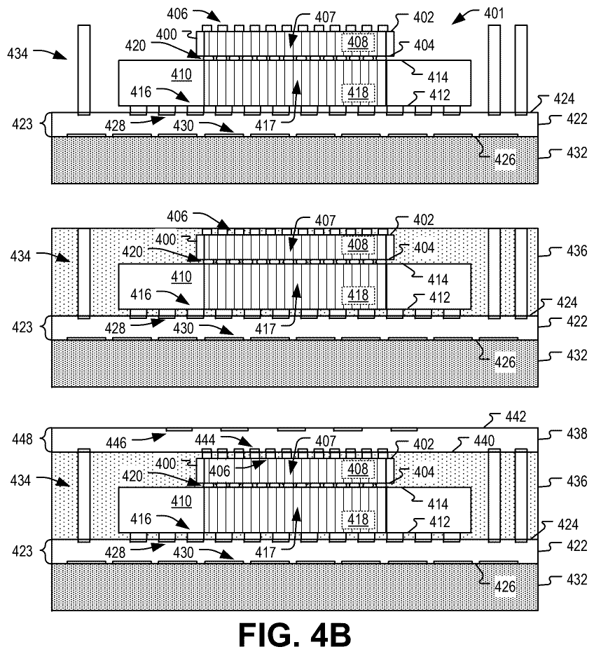

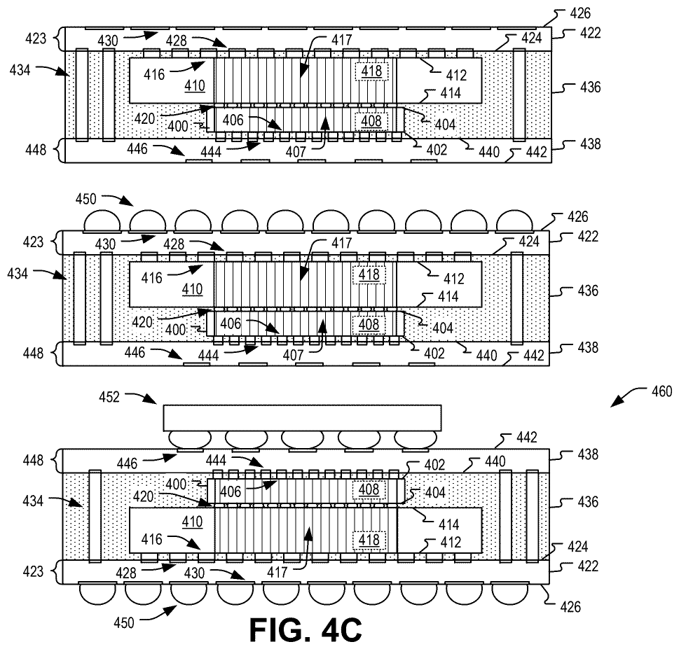

In some embodiments, the substrate 106 also includes a second set of redistribution layers coupled to the first side 124 (e.g., the front side or face) of the second die 104. In such embodiments, the second set of redistribution layers define conductive paths between one or more of the on-package contacts 136 and one or more of the off-package contacts 154 (e.g., one or more of the set of pads). Examples of process flow stages associated with forming a device that includes a package substrate having redistribution layers are described further herein with reference to FIGS. 3A-3D and 4A-4C. Alternatively, the substrate 106 may include or correspond to a laminate substrate that includes a set of laminate layers coupled to the first side 124 (e.g., the front side or face) of the second die 104. In such embodiments, the set of laminate layers define conductive paths between one or more of the on-package contacts 136 and one or more of the off-package contacts 154 (e.g., one or more of the set of pads). Examples of process flow stages associated with forming a device that includes a laminate substrate as a package substrate are described further herein with reference to FIGS. 3A-3C and 3E-3F.

Optionally, the first die 102, the second die 104, the substrate 106, and the interposer 108 (or portions thereof) are at least partially encapsulated within mold compound 140. The device 100 also includes electrical interconnects 138 (e.g., a set of electrical interconnects) between the substrate 106 and the interposer 108. The electrical interconnects 138 may extend through the mold compound 140 from the first side 146 of the interposer 108 (e.g., from one or more of the on-package contacts 134) to the first side 150 of the substrate 106 (e.g., to one or more of the on-package contacts 136). The electrical interconnects 138 may include through-mold vias (TMVs), conductive pillars, or the like, and may be disposed within the mold compound 140 and at least partially surround the first die 102 and the second die 104. For example, as shown in FIG. 1, at least some of the electrical interconnects 138 are disposed to the left side of the dies 102, 104 and at least some of the electrical interconnects 138 are disposed to the right side of the dies 102, 104. In some embodiments, the electrical interconnects 138 may be configured to provide power and ground connections to the first die 102, the second die 104, an external resource coupled to the off-package contacts 144, or a combination thereof.

In a particular implementation, the device 100 includes a first die (e.g., the first die 102) and a second die (e.g., the second die 104). The first die includes a first set of external contacts (e.g., the external contacts 114) on a first side (e.g., the first side 120) of the first die. The first die also includes a first plurality of TSVs (e.g., the first TSVs 130) that extend between the first side of the first die and a second side (e.g., the second side 122) of the first die. The first die also includes interface or control circuitry (e.g., the interface or control circuitry 110) proximate to the first side of the first die. The second die includes a second set of external contacts (e.g., the external contacts 116) on a first side (e.g., the first side 124) of the second die. The second die also include a second plurality of TSVs (e.g., the second TSVs 132) that extend between the first side of the second die and a second side (e.g., the second side 126) of the second die. The second die also includes processor circuitry (e.g., the processor circuitry 112) proximate to the first side of the second die and configured to access an external resource via the interface or control circuitry.

It should be understood that the device 100 may include additional components, other components, fewer components, or a combination thereof, to support the functionality described herein. As non-limiting examples, the device 100 may include additional IC devices, additional layers, additional dies, additional packages, additional interconnects, additional structures, other components, different components, or a combination thereof, to support the functionality and technical advantages disclosed herein.

The device 100 thus experiences less delay in communications between the second die 104 and an external resource, and the device 100 as a smaller package size, as compared to other packaged semiconductor devices that provide interfacing between a SoC and an external resource. For example, because the communication channels between the processor circuitry 112, the interface or control circuitry 110, and an external resource that can be coupled to the off-package contacts 144 are defined by the first TSVs 130, the second TSVs 132, and the interposer 108, these communication channels are shorter than those from a center of a processer to the locations of the protocol control interfaces along the edges of the package substrate. A technical advantage of reducing the communication channels between the processor circuitry 112, the interface or control circuitry 110, and the external resource by the stacked-chip configuration of the first die 102 and the second die 104 (which include the first TSVs 130 and the second TSVs 132, respectively), is reduced communication delay and/or reduced signal loss as compared to conventional packaged semiconductor devices in which the circuitry of the first die 102 and the second die 104 is included in a single die. Additionally, reducing the lengths of these communication channels without significantly increasing the height of the device 100 reduces a package size (e.g., by 10-20% in some examples) of the device 100 as compared to other packaged semiconductor devices, which can reduce cost and complexity of fabricating the device 100. These benefits can be achieved in a packaged semiconductor device that achieves input/output (IO) pitch less than 80 micrometers (μm) and that enables different nodes between interface or control dies and SoC logic dies, which provides greater flexibility in design and/or fabrication processes used by a foundry. Such benefits may multiply and/or scale if multiple memory dies (or other external resources) are to be included in a chipset.

FIG. 2 illustrates a cross-sectional profile view of a particular implementation of a packaged semiconductor device that includes interface or control interconnections between multiple dies and is generally designated as a packaged semiconductor device 200. The packaged semiconductor device 200 of FIG. 2 includes many of the same components and features as are described above with reference to FIG. 1. Such components and features are physically and operationally the same as described above with reference to FIG. 1 and are labeled in FIG. 2 using the same reference numbers. In some implementations, the packaged semiconductor device 200 includes all of the same features and components as the device 100 of FIG. 1; however, some components and features illustrated in FIG. 1 have been omitted from (or are not labeled with reference numbers in) FIG. 2 for simplicity of illustration and to highlight differences between the device 100 and the packaged semiconductor device 200. Omission of such features and reference numbers should not be understood as limiting the features and components of FIG. 2 to only those specifically called out below. For example, while FIG. 2 does not show the on-package contacts 134 and the on-package contacts 136 of FIG. 1, such omissions are for ease of understanding the illustration in FIG. 2, and the packaged semiconductor device 200 can include the on-package contacts 134 and the on-package contacts 136.

In the example shown in FIG. 2, the packaged semiconductor device 200 includes the device 100 (e.g., the first die 102, the second die 104, the substrate 106, the interposer 108, the electrical interconnects 138, and, optionally, the mold compound 140). The packaged semiconductor device 200 also includes a third die 202 coupled to the substrate 106 and a PCB 206 coupled to the substrate 106. For example, the third die 202 may include contacts 204 that are coupled to the off-package contacts 144 of the interposer 108, and the PCB 206 may be coupled to the off-package contacts 154 of the substrate 106. Coupling the substrate 106 may couple the processor circuitry 112 to one or more other external resources via the PCB 206.

The third die 202 may include or correspond to an external resource that is external to the device 100 (e.g., a packaged semiconductor device). In some embodiments, the third die 202 includes or corresponds to a memory die, such as a DRAM, and the interface or control circuitry 110 of the first die 102 is DRAM protocol control circuitry. For example, the third die 202 may be a DDR-compliant DRAM, and the interface or control circuitry 110 may include DDR PHY circuitry, memory controller, or a combination thereof, that enables the processor circuitry 112 to access the DRAM (e.g., the third die 202) using a DDR protocol. In other embodiments, the third die 202 (e.g., the DRAM) may comply with another memory protocol, such as a UFS protocol, or the third die 202 may be a different type of die.

The interface or control circuitry 110 may enable the processor circuitry 112 to access the third die 202 via one or more signal paths, such as an illustrative signal path 208 shown in FIG. 2. In this example, the signal path 208 includes one or more of the second TSVs 132, one or more of the first TSVs 130, one or more of the external contacts 114, the redistribution layers 142, one or more of the external contacts 114, and one or more of the contacts 204. In a particular example, the interface or control circuitry 110 may enable the processor circuitry 112 to perform a memory access operation, such as a read operation or a write operation, with respect to the third die 202 using communications over the signal path 208.

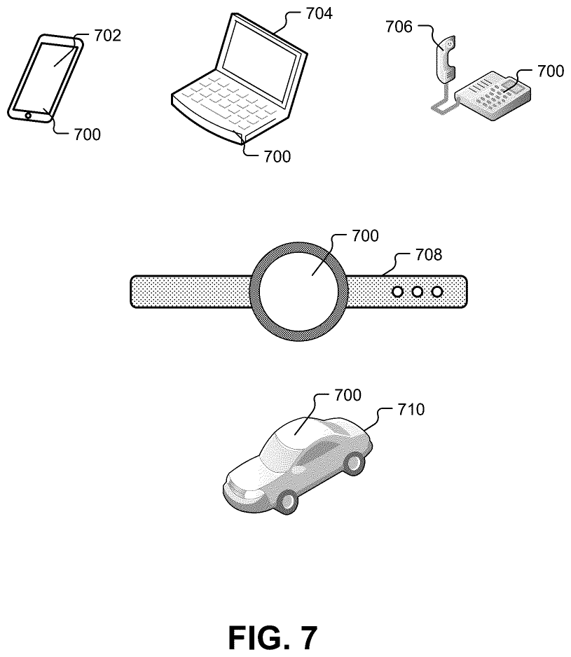

In some implementations, the packaged semiconductor device 200 can be integrated in a smartphone, a tablet computer, a fixed location terminal device, an automobile, a wearable electronic device, a laptop computer, or some combination thereof, as described in more detail below with reference to FIG. 7. As described with reference to FIG. 2, the packaged semiconductor device 200 includes the first die 102 (including the first TSVs 130) and the second die 104 (including the second TSVs 132) in a stacked configuration to provide interface or control interconnections between the second die 104 and the third die 202 of the packaged semiconductor device 200. A technical advantage of these interface or control interconnections is reduced communication delay and/or reduced signal loss between the dies, and reduced package size of the packaged semiconductor device 200, as compared to conventional processor and memory packaged semiconductor devices, as explained above with reference to FIG. 1. Additionally, because the device 100 can be manufactured without including the third die 202, a vendor has increased flexibility to either attach their own memory die before selling the packaged semiconductor device 200 or selling the device 100 to a customer and enabling the customer to attach their own memory die to form the packaged semiconductor device 200.

Although three dies 102, 104, 202 are shown in FIG. 2, in other examples, the packaged semiconductor device 200 can include more than three dies. Further, in some cases, one or both of the dies 104, 202 of FIG. 2 can include or correspond to a stacked IC device that includes two or more chiplets stacked one upon another and electrically interconnected. Using chiplets arranged and interconnected as a stacked IC can provide various benefits as compared to providing the same functional circuitry in one monolithic chip. For example, each chiplet is smaller than a monolithic die including all of the same functional circuit blocks would be. Since yield loss in IC manufacturing tends to increase as the die size increases, using smaller dies can reduce yield loss (i.e., increase yield) of the IC manufacturing process. Another benefit is that the chiplets can be fabricated in different locations and/or by different manufacturers, and in some cases, using different fabrication technologies (e.g., different fabrication technology nodes). As an example, one chiplet can include components (e.g., interconnects, transistors, etc.) that have a first minimum size, and another chiplet can include components (e.g., interconnects, transistors, etc.) that have a second minimum size, where the second minimum size is greater than the first minimum size. In contrast, all of the circuitry of a monolithic die is fabricated using the same fabrication technologies and equipment. As a result, when manufacturing a monolithic die, the entire die may be subject to the tightest manufacturing constraint of the most complex component of the monolithic die. In contrast, when using chiplets, different chiplets can be manufactured using different fabrication technologies (e.g., different fabrication technology nodes), and only the chiplet or chiplets that include the most complex components are subjected to the tightest manufacturing constraints. In this arrangement, chiplets fabricated using less expensive and/or higher yield fabrication technologies can be integrated with chiplets fabricated using more expensive and/or lower yield fabrication technologies Still further, in some cases, as technology improves, the design of a chiplet can be changed. Chiplet stacking allows such new chiplet designs to be integrated with older chiplet designs to form stacked IC devices, which improves manufacturing flexibility and reduces design costs.

### Exemplary Sequences for Fabricating a Device Including Interface or Control Interconnections Between Multiple Dies

In some implementations, fabricating a device including interface or control interconnections between multiple dies (e.g., any of the devices 100, 200) includes several processes. FIGS. 3A-F illustrate an exemplary sequence for fabricating or providing a device that includes interface or control interconnections between multiple dies, as described with reference to any of FIGS. 1-2. FIGS. 4A-C illustrate another exemplary sequence for fabricating or providing a device that includes interface or control interconnections between multiple dies, as described with reference to any of FIGS. 1-2. In some implementations, the sequences of FIGS. 3A-F and 4A-C may be used to provide (e.g., during fabrication of) one or more of the device 100 of FIG. 1 or the packaged semiconductor device 200 of FIG. 2.

It should be noted that the sequences of FIGS. 3A-F and 4A-C may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequences, which are numbered (using circled numbers) in FIGS. 3A-F and 4A-C. Each of the various stages of the sequences illustrated in FIGS. 3A-F and 4A-C show a single integrated device being formed. In other implementations, a plurality of integrated devices can be formed concurrently.

Stage 1 of FIG. 3A illustrates a state after a first die 300 is obtained. For example, as part of Stage 1, the first die 300 may be manufactured or otherwise obtained. The first die 300 includes external contacts 306 (e.g., a first set of external contacts) on a first side 302 of the first die 300, first TSVs 307 (e.g., a first plurality of TSVs) that extend between the first side 302 of the first die 300 and a second side 304 of the first die 300 that is opposite to the first side 302, and interface or control circuitry 308 proximate to the first side 302 of the first die 300. In some embodiments, the first TSVs 307 include or correspond to through-silicon vias that are formed during manufacture of the first die 300. The first TSVs 307 may extend from the second side 304 of the first die 300 to one or more layers at or near the first side 302 of the first die 300, and thus be between the first side 302 and the second side 304. For example, the first TSVs 307 may extend from the back (e.g., the second side 304) to a metal layer on front of the first die 300 that has one or more metal layers on top (e.g., for redistribution routing). As another example, the first TSVs 307 may extend from the second side 304 to the first side 302 (e.g., from the opposite external metal layers of the first die 300). The interface or control circuitry 308 may include IF circuitry, one or more controllers, or a combination thereof. In some embodiments, the interface or control circuitry 308 may include a DDR-type DRAM bus interface or other DDR interface circuitry, and the interface or control circuitry 308 may be configured to convert signals between a DDR protocol used by a DDR memory and a PHY protocol used by the IF circuitry and a processor. In other embodiments, the interface or control circuitry 308 may operate in accordance with a different protocol, such as a UFS protocol, as a non-limiting example.

Stage 2 illustrates a state after the first die 300 is attached to a carrier structure 310. For example, as part of Stage 2, the first die 300 is attached to the carrier structure 310 with the second side 304 (e.g., the side with the exposed first TSVs 307) facing the carrier structure 310.

Stage 3 illustrates a state after mold compound 312 is applied to at least partially encapsulate the first die 300 and after an interposer 314 is coupled to the first die 300. For example, as part of Stage 3, after the mold compound 312 is applied on the first die 300 and the carrier structure 310, redistribution layers 316 (e.g., a first set of redistribution layers) are formed on the first side 302 of the first die 300 and the mold compound 312. The redistribution layers 316 include a set of metal layers that are patterned to form conductive features (e.g., lines and vias) that are separated from one another by dielectric layers.

The redistribution layers 316 can be formed, for example, using a sequence of operations that form dielectric layers and patterned metal layers. For example, each of the dielectric layers can be formed using operations such as deposition or thin film application of a dielectric material. In some cases, the dielectric material can be patterned using photolithography techniques (e.g., exposure and development). Each of the metal layers can be formed using operations such as deposition or thin film application. For example, a patterning layer can be formed (e.g. using photolithography techniques) and metal can be deposited on the patterning layer to form a patterned metal layer. As another example, a metal foil can be applied and patterned using subtractive techniques, such as etching guided by a patterned layer. Metal layers can be formed on portions of a bottom metal layer (in the orientation illustrated in FIG. 3A) and/or underbump metallization layers can be formed on portions of a top metal layer (in the orientation illustrated in FIG. 3A) that correspond to contacts of the redistribution layers 316. The contacts of the redistribution layers 316 can be interconnected by conductors of the metal layers to form conductive paths therebetween.

The interposer 314 includes or corresponds to the redistribution layers 316. The interposer 314 also includes on-package contacts 322 and off-package contacts 324, which may be formed in the redistribution layers 316 as described above. For example, the on-package contacts 322 may be formed on a first side 318 of the interposer 314 and the off-package contacts 324 may be formed on a second side 320 of the interposer 314 that is opposite to the first side 318. At least a portion of the on-package contacts 322 of the interposer 314 may be electrically coupled to the external contacts 306 of the first die 300.

Stage 4 of FIG. 3B illustrates a state after removal of the first die 300 from the carrier structure 310 and after the interposer 314 is attached to a carrier structure 326. For example, as part of Stage 4, the second side 304 of the first die 300 (and the mold compound 312) may be separated from the carrier structure 310. After separation, the die-interposer structure may be rotated approximately 180 degrees such that the second side 320 of the interposer 314 is facing down (in the orientation shown in FIG. 3B) and the second side 320 of the interposer 314 may be attached to the carrier structure 326 (e.g., the same or different carrier structure as was attached to the second side 304 of the first die 300).

Stage 5 illustrates a state after a second die 330 is obtained. For example, as part of Stage 5, the second die 330 may be manufactured or otherwise obtained. The second die 330 includes external contacts 336 (e.g., a second set of external contacts) on a first side 332 of the second die 330, second TSVs 337 (e.g., a second plurality of TSVs) that extend between the first side 332 of the second die 330 and a second side 334 of the second die 330 that is opposite to the first side 332, and processor circuitry 338 proximate to the first side 332 of the second die 330 and configured to access an external resource via the interface or control circuitry 308. In some embodiments, the second TSVs 337 include or correspond to through-silicon vias that are formed during manufacture of the second die 330. The second TSVs 337 may extend from the second side 334 of the second die 330 to one or more layers at or near the first side 332 of the second die 330, and thus be between the first side 332 and the second side 334. For example, the second TSVs 337 may extend from the back (e.g., the second side 334) to a metal layer on front of the second die 330 that has one or more metal layers on top (e.g., for redistribution routing). As another example, the second TSVs 337 may extend from the second side 334 to the first side 332 (e.g., from the opposite external metal layers of the second die 330). The processor circuitry 338 may include or correspond to an SoC or other processor that is configured to access an external resource, such as a DRAM or other type of memory, via the interface or control circuitry 308.

Stage 6 illustrates a state after electrically coupling the second die 330 to the first die 300. For example, as part of Stage 6, the second side 334 of the second die 330 may be attached to the second side 304 of the first die 300 such that the dies 300, 330 are coupled back-to-back (e.g., with back sides or faces together). The second die 330 may be electrically coupled to the first die 300 using either micro-bump bonding techniques or hybrid bonding techniques. For example, electrically coupling the second die 330 to the first die 300 includes forming joints 339 between first TSVs 307 and the second TSVs 337 using micro-bump bonding or hybrid bonding. The joints 339 may include solder, copper, or another metal or conductive substance. Signal paths between the second die 330 and the first die 300 include corresponding TSVs of the second TSVs 337 and corresponding TSVs of the first TSVs 307 (and in some embodiments, the joints 339) after the second die 330 is attached to the first die 300.

Stage 7 of FIG. 3C illustrates a state after cavities are formed within the mold compound 312 and electrical interconnects 340 are formed at least partially within the cavities. For example, as part of Stage 7, cavities may be formed within the mold compound 312 by etching or another process that forms openings within the mold compound 312 along first edges (e.g., left edges in the orientation shown in FIG. 3C) of the dies 300, 330 and along second edges (e.g., right edges in the orientation shown in FIG. 3C) of the dies 300, 330. After forming the cavities, the cavities may be plated, such as by using through mold via (TMV) plating process or a through integrated fan-out via (TIV) plating process, to form the electrical interconnects 340. In some embodiments, the electrical interconnects 340 may include copper plating that may extend above the mold compound 312 as one or more copper pillars.

Stage 8 illustrates a state after applying more of the mold compound 312 to at least partially encapsulate the second die 330 and the electrical interconnects 340. For example, as part of Stage 8, a second mold deposition process (e.g., an overmold process) may be performed to deposit additional mold compound 312 on the mold compound 312, the second die 330, the electrical interconnects 340, or a combination thereof, such that a surface of the mold compound 312 is at or above a surface of the external contacts 336 of the second die 330. Although described as being performed after the operations of Stage 7, in some other embodiments, the additional mold compound 312 may be deposited after the second die 330 is electrically coupled to the first die 300 and before the cavities and the electrical interconnects 340 are formed. Additionally, or alternatively, Stage 8 may also include back grinding to expose the external contacts 336 of the second die 330 and pads of the electrical interconnects 340 in addition to preparation for attaching a substrate (e.g., preparation for bumping if a laminate substrate is to be attached or preparation for formation of additional redistribution layers if the substrate is to include redistribution layers). If a laminate substrate is to be attached, the sequence progresses to Stage 12 of FIG. 3E, as further described herein. Alternatively, if a substrate that includes redistribution layers is to be attached, the sequence continues to Stage 9 of FIG. 3D.

Stage 9 of FIG. 3D illustrates a state after removal of the interposer 314 from the carrier structure 326 and after a substrate 342 is coupled to the second die 330. For example, as part of Stage 9, redistribution layers 343 (e.g., a second set of redistribution layers) are formed on the first side 332 of the second die 330 and the mold compound 312. The redistribution layers 343 include a set of metal layers that are patterned to form conductive features (e.g., lines and vias) that are separated from one another by dielectric layers, and may be formed as described above for the redistribution layers 316. The redistribution layers 343 form the substrate 342 that has a first side 344 and a second side 346 that is opposite to the first side 344. The substrate 342 may include on-package contacts 348 on the first side 344 of the substrate 342 and off-package contacts 350 on the second side 346 of the substrate 342. Attaching the substrate 342 to the second die 330 may include electrically coupling the on-package contacts 348 of the substrate 342 to the external contacts 336 of the second die 330. The carrier structure 326 may be removed before or after formation of the redistribution layers 343.

Stage 10 illustrates a state after off-package conductors 352 are electrically coupled to the off-package contacts 350 of the substrate 342. For example, as part of Stage 10, BGA balls, solder balls, or other conductive structures may be electrically coupled to the off-package contacts 350 of the substrate 342 to form the off-package conductors 352 that are configured facilitate an electrical connection with another device or a PCB once the off-package conductors 352 are coupled to such a device or PCB. In some implementations, Stages 1-10 can be performed at a strip level or a panel level. For example, the substrate 342 illustrated in Stages 9-10 can correspond to a portion of a strip of package substrates or a panel of package substrates. In such implementations, Stage 10 illustrates a state after package singulation, such as by cutting the strip or panel of package substrates to form an individual integrated device package, as depicted in Stage 11. Additionally, during or after package singulation, the integrated device package may be rotated approximately 180 degrees from the orientation depicted in FIG. 3C with reference to Stage 9.

Stage 11 illustrates a state after an external resource is coupled to the interposer 314. For example, as part of Stage 11, a third die 354 may be electrically coupled to the off-package contacts 324 of the interposer 314. In some embodiments, the third die 354 is a DRAM, such as a DDR-compliant DRAM. In other embodiments, the third die 354 is a memory that is compliant with a different protocol, such as a UFS protocol, or another type of die that communicates according to one or more protocols that are different than the communication protocols of the processor circuitry 338. The interface or control circuitry 308 facilitates communication between the processor circuitry 338 and the third die 354 and enables the processor circuitry 338 to access the third die 354. For example, control and data signals between the interface or control circuitry 308, processor circuitry 338 and the third die 354 may be communicated along signal paths that extend through the second TSVs 337, the first TSVs 307, the on-package contacts 322 of the interposer 314, the redistribution layers 316, and the off-package contacts 324 of the interposer 314. These signal paths provide interface or control interconnections between the first die 300, the second die 330, and the third die 354 that have shorter distances than channels of conventional packaged semiconductor devices in which protocol control and interface circuitry is disposed along the outer edges of a packaged substrate, thereby reducing communication delay and/or signal loss, as well as package size, as compared to the conventional packaged semiconductor devices.

Formation of a packaged semiconductor device 360 (e.g., a device including interface or control interconnections between multiple dies) is complete after Stage 11 of FIG. 3D. In the example illustrated, the packaged semiconductor device 360 includes the first die 300, which is an example of the first die 102 of FIGS. 1-2. The packaged semiconductor device 360 also includes the second die 330, which is an example of the second die 104 of FIGS. 1-2. The packaged semiconductor device 360 also includes the interposer 314, which is an example of the interposer 108 of FIGS. 1-2. The packaged semiconductor device 360 also includes the third die 354, which is an example of the third die 202 of FIG. 2. The packaged semiconductor device 360 also includes the substrate 342, which is an example of the substrate 106 of FIGS. 1-2. The packaged semiconductor device 360 also includes the electrical interconnects 340, which are an example of the electrical interconnects 138 of FIGS. 1-2.

Alternatively, if a laminate substrate is to be attached to the second die 330, the sequence progresses from Stage 8 to Stage 12. Stage 12 of FIG. 3E illustrates a state after conductive connectors 370 (e.g., a set of conductive connectors) are formed on the electrical interconnects 340 and the external contacts 336 of the second die 330. For example, as part of Stage 12, the exposed portions of the electrical interconnects 340 and the external contacts 336 of the second die 330 may be electrically coupled to the conductive connectors 370, such as using a flip-chip bump formation process. In some embodiments, the conductive connectors 370 include solder bumps or metal posts.

In some implementations, Stages 1-8 and 12 can be performed at a strip level or a panel level. For example, the interposer 314 illustrated in Stages 6-8 and 12 can correspond to a portion of a strip of interposers or a panel of interposers. In such implementations, after Stage 12, the carrier structure 326 may be removed and package singulation may be performed, such as by cutting the strip or panel of interposers to form an individual integrated IC assembly. Additionally, during or after package singulation, the integrated IC assembly may be rotated approximately 180 degrees from the orientation depicted in FIG. 3E with reference to Stage 12.

Stage 13 illustrates a state after the integrated IC device (e.g., including the dies 300, 330 and the interposer 314) is attached to a substrate 372. For example, as part of Stage 13, a first side 374 of the substrate 372 is electrically coupled to the first side 332 of the second die 330 and the electrical interconnects 340. To illustrate, the substrate 372 may be a laminate substrate that includes on-package contacts 378 on the first side 374 of the substrate 372, and the on-package contacts 378 of the substrate 372 may be electrically coupled to the external contacts 336 of the second die 330 and the electrical interconnects 340. In some examples, the substrate 372 is attached to the second die 330 and the electrical interconnects 340 using thermal compression bonding (TCB), mass reflow, optional underfill, or the like. Stage 13 may also include forming off-package contacts 380 (e.g., a second set of off-package contacts) on a second side 376 of the substrate 372 that is opposite to the first side 374 of the substrate 372. One or more of the on-package contacts 378 may be electrically coupled to the off-package contacts 380 via one or more conductors (e.g., metal lines, vias, etc.) within the substrate 372.

Stage 14 illustrates a state after off-package conductors 382 are formed on the second side 376 of the substrate 372. For example, as part of Stage 14, BGA balls, solder balls, or other conductive structures may be electrically coupled to the off-package contacts 380 of the substrate 372 to form the off-package conductors 382 that are configured facilitate an electrical connection with another device or a PCB once the off-package conductors 382 are coupled to such a device or PCB.

Stage 15 of FIG. 3F illustrates a state after an external resource is coupled to the interposer 314. For example, as part of Stage 15, a third die 384 may be electrically coupled to the off-package contacts 324 of the interposer 314, such as using a surface mount technology (SMT) process. In some embodiments, the third die 384 is a DRAM, such as a DDR-compliant DRAM. In other embodiments, the third die 384 is a memory that is compliant with a different protocol, such as a UFS protocol, or another type of die that communicates according to one or more protocols that are different than the communication protocols of the processor circuitry 338. The interface or control circuitry 308 facilitates communication between the processor circuitry 338 and third die 384 and enables the processor circuitry 338 to access the third die 384. For example, control and data signals between the interface or control circuitry 308, processor circuitry 338 and the third die 384 may be communicated along signal paths that extend through the second TSVs 337, the first TSVs 307, the on-package contacts 322 of the interposer 314, the redistribution layers 316, and the off-package contacts 324 of the interposer 314. These signal paths provide interface or control interconnections between the first die 300, the second die 330, and the third die 384 that have shorter distances than channels of conventional packaged semiconductor devices in which protocol control and interface circuitry is disposed along the outer edges of a packaged substrate, thereby reducing communication delay and/or signal loss, as well as package size, as compared to the conventional packaged semiconductor devices.

Formation of a packaged semiconductor device 390 (e.g., a device including interface or control interconnections between multiple dies) is complete after Stage 15 of FIG. 3F. In the example illustrated, the packaged semiconductor device 390 includes the first die 300, which is an example of the first die 102 of FIGS. 1-2. The packaged semiconductor device 390 also includes the second die 330, which is an example of the second die 104 of FIGS. 1-2. The packaged semiconductor device 390 also includes the interposer 314, which is an example of the interposer 108 of FIGS. 1-2. The packaged semiconductor device 390 also includes the third die 384, which is an example of the third die 202 of FIG. 2. The packaged semiconductor device 390 also includes the substrate 372, which is an example of the substrate 106 of FIGS. 1-2. The packaged semiconductor device 390 also includes the electrical interconnects 340, which are an example of the electrical interconnects 138 of FIGS. 1-2.

FIGS. 4A-C illustrate a sequence in which multiple dies are obtained as a single assembly, as compared to the sequence of FIGS. 3A-F in which the dies are obtained individually. Stage 1 of FIG. 4A illustrates a state after an assembly 401 that includes a first die 400 coupled to a second die 410 is obtained. For example, as part of Stage 1, the first die 400 and the second die 410 may be manufactured or otherwise obtained, and the first die 400 may be attached to the second die 410, such as using a 3D stacking process, to form the assembly 401.

The first die 400 includes external contacts 406 (e.g., a first set of external contacts) on a first side 402 of the first die 400, first TSVs 407 (e.g., a first plurality of TSVs) that extend between the first side 402 of the first die 400 and a second side 404 of the first die 400 that is opposite to the first side 402, and interface or control circuitry 408 proximate to the first side 402 of the first die 400. In some embodiments, the first TSVs 407 include or correspond to through-silicon vias that are formed during manufacture of the first die 400. The first TSVs 407 may extend from the second side 404 of the first die 400 to one or more layers at or near the first side 402 of the first die 400, and thus be between the first side 402 and the second side 404. For example, the first TSVs 407 may extend from the back (e.g., the second side 404) to a metal layer on front of the first die 400 that has one or more metal layers on top (e.g., for redistribution routing). As another example, the first TSVs 407 may extend from the second side 404 to the first side 402 (e.g., from the opposite external metal layers of the first die 400). The interface or control circuitry 408 may include IF circuitry, one or more controllers, or a combination thereof. In some embodiments, the interface or control circuitry 408 may include a DDR-type DRAM bus interface or other DDR interface circuitry, and the interface or control circuitry 408 may be configured to convert signals between a DDR protocol used by a DDR memory and a PHY protocol used by the IF circuitry and a processor. In other embodiments, the interface or control circuitry 408 may operate in accordance with a different protocol, such as a UFS protocol, as a non-limiting example.

The second die 410 includes external contacts 416 (e.g., a second set of external contacts) on a first side 412 of the second die 410, second TSVs 417 (e.g., a second plurality of TSVs) that extend between the first side 412 of the second die 410 and a second side 414 of the second die 410 that is opposite to the first side 412, and processor circuitry 418 proximate to the first side 412 of the second die 410 and configured to access an external resource via the interface or control circuitry 408. In some embodiments, the second TSVs 417 include or correspond to through-silicon vias that are formed during manufacture of the second die 410. The second TSVs 417 may extend from the second side 414 of the second die 410 to one or more layers at or near the first side 412 of the second die 410, and thus be between the first side 412 and the second side 414. For example, the second TSVs 417 may extend from the back (e.g., the second side 414) to a metal layer on front of the second die 410 that has one or more metal layers on top (e.g., for redistribution routing). As another example, the second TSVs 417 may extend from the second side 414 to the first side 412 (e.g., from the opposite external metal layers of the second die 410). The processor circuitry 418 may include or correspond to an SoC or other processor that is configured to access an external resource, such as a DRAM or other type of memory, via the interface or control circuitry 408.

In some embodiments, the assembly 401 is formed by attaching the second side 414 of the second die 410 to the second side 404 of the first die 400 such that the dies 400, 410 are coupled back-to-back (e.g., with back sides or faces together). The second die 410 may be electrically coupled to the first die 400 using either micro-bump bonding techniques or hybrid bonding techniques. For example, electrically coupling the second die 410 to the first die 400 may include forming joints 420 between first TSVs 407 and the second TSVs 417 using micro-bump bonding or hybrid bonding. The joints 420 may include solder, copper, or another metal or conductive substance. Signal paths between the second die 410 and the first die 400 include corresponding TSVs of the second TSVs 417 and corresponding TSVs of the first TSVs 407 (and in some embodiments, the joints 420) after the second die 410 is attached to the first die 400. Although a width of the first die 400 is illustrated in FIG. 4A as being smaller than a width of the second die 410, in some other implementations, the assembly 401 may be formed using wafer-level stacking, such that two wafers are stacked and sawed off to the same size. In such implementations, the width of the first die 400 is the same as the width of the second die 410, which may improve heat management associated with the assembly 401 by including additional silicon (e.g., the first die 400) above the second die 410 to spread or dissipate heat.

Stage 2 illustrates a state after a substrate 422 is coupled to a carrier structure 432. For example, as part of Stage 2, the substrate 422 may be formed on and/or attached to a top side (in the orientation shown in FIG. 4A) of the carrier structure 432. In some embodiments, the substrate 422 is a laminate substrate that is formed on and/or attached to the carrier structure 432. In some other embodiments, the substrate 422 includes redistribution layers 423 (e.g., a second set of redistribution layers) that are formed on the carrier structure 432. The redistribution layers 423 include a set of metal layers that are patterned to form conductive features (e.g., lines and vias) that are separated from one another by dielectric layers.

In embodiments that include the redistribution layers 423, the redistribution layers 423 can be formed, for example, using a sequence of operations that form dielectric layers and patterned metal layers. For example, each of the dielectric layers can be formed using operations such as deposition or thin film application of a dielectric material. In some cases, the dielectric material can be patterned using photolithography techniques (e.g., exposure and development). Each of the metal layers can be formed using operations such as deposition or thin film application. For example, a patterning layer can be formed (e.g. using photolithography techniques) and metal can be deposited on the patterning layer to form a patterned metal layer. As another example, a metal foil can be applied and patterned using subtractive techniques, such as etching guided by a patterned layer. Metal layers can be formed on portions of a bottom metal layer (in the orientation illustrated in FIG. 4A) and/or underbump metallization layers can be formed on portions of a top metal layer (in the orientation illustrated in FIG. 4A) that correspond to contacts of the redistribution layers 423. The contacts of the redistribution layers 423 can be interconnected by conductors of the metal layers to form conductive paths therebetween.

The substrate 422 also includes on-package contacts 428 and off-package contacts 430. For example, the on-package contacts 428 may be formed on a first side 424 of the substrate 422 and the off-package contacts 430 may be formed on a second side 426 of the substrate 422 that is opposite to the first side 424. The on-package contacts 428 and the off-package contacts 430 may be formed in the redistribution layers 423 as described above or in layers of a laminate substrate, depending on what type of substrate is coupled to the carrier structure 432.

Stage 3 illustrates a state after coupling conductive pillars 434 (e.g., a set of conductive pillars) to the first side 424 of the substrate 422. For example, as part of Stage 3, the conductive pillars 434, which may be tall pillars, may be formed on and electrically coupled to some of the on-package contacts 428 on the first side 424 of the substrate 422. The conductive pillars 434 may include copper or another metal or conductive material. The conductive pillars 434 may be electrically coupled to the left or to the right (in the orientation shown in FIG. 4A) of the portion of on-package contacts 428 which will be coupled to the assembly 401 in a later Stage.

Stage 4 of FIG. 4B illustrates a state after coupling the assembly 401 to the first side 424 of the substrate 422. For example, as part of Stage 4, the external contacts 416 of the second die 410 are electrically coupled to at least a portion of the on-package contacts 428 of the substrate 422. Stage 5 illustrates a state after mold compound 436 is applied to at least partially encapsulate the first die 400, the second die 410, the conductive pillars 434, and the substrate 422. For example, as part of Stage 5, the mold compound 436 may be deposited as part of an overmolding process. In some embodiments, Stage 5 also includes grinding a top surface (in the orientation shown in FIG. 4B) of the mold compound 436 to expose top portions of the conductive pillars 434 and the external contacts 406 of the first die 400.

Stage 6 illustrates a state after coupling an interposer 438 to the first side 402 of the first die 400. For example, as part of Stage 6, redistribution layers 448 (e.g., a first set of redistribution layers) are formed on the first side 402 of the first die 400 and the mold compound 436. The redistribution layers 448 include a set of metal layers that are patterned to form conductive features (e.g., lines and vias) that are separated from one another by dielectric layers, and the redistribution layers 448 may be formed as described above for the redistribution layers 423.

The interposer 438 includes or corresponds to the redistribution layers 448. The interposer 438 also includes on-package contacts 444 and off-package contacts 446, which may be formed in the redistribution layers 448. For example, the on-package contacts 444 may be formed on a first side 440 of the interposer 438 and the off-package contacts 446 may be formed on a second side 442 of the interposer 438 that is opposite to the first side 440. A portion of the on-package contacts 444 of the interposer 438 may be electrically coupled to the external contacts 406 of the first die 400, and others of the on-package contacts 444 may be electrically coupled to the conductive pillars 434.

Stage 7 of FIG. 4C illustrates a state after the carrier structure 432 is removed from the integrated IC device structure. For example, as part of Stage 7, the carrier structure 432 may be detached from the second side 426 of the substrate 422. Additionally, Stage 7 may include rotating the integrated IC device structure approximately 180 degrees from the orientation shown at Stage 6 in FIG. 4B to prepare the substrate 422 for attaching off-package conductors.

Stage 8 illustrates a state after off-package conductors 450 are formed on the second side 426 of the substrate 422. For example, as part of Stage 8, BGA balls, solder balls, or other conductive structures may be electrically coupled to the off-package contacts 430 of the substrate 422 to form the off-package conductors 450 that are configured to facilitate an electrical connection with another device or a PCB once the off-package conductors 450 are coupled to such a device or PCB.

Stage 9 illustrates a state after an external resource is coupled to the interposer 438. For example, as part of Stage 9, a third die 452 may be electrically coupled to the off-package contacts 446 of the interposer 438, such as using an SMT process. In some embodiments, the third die 452 is a DRAM, such as a DDR-compliant DRAM. In other embodiments, the third die 452 is a memory that is compliant with a different protocol, such as a UFS protocol, or another type of die that communicates according to one or more protocols that are different than the communication protocols of the processor circuitry 418. The interface or control circuitry 408 facilitates communication between the processor circuitry 418 and the third die 452 and enables the processor circuitry 418 to access the third die 452. For example, control and data signals between the interface or control circuitry 408, processor circuitry 418 and the third die 452 may be communicated along signal paths that extend through the second TSVs 417, the first TSVs 407, the on-package contacts 444 of the interposer 438, the redistribution layers 448, and the off-package contacts 446 of the interposer 438. These signal paths provide interface or control interconnections between the first die 400, the second die 410, and the third die 452 that have shorter distances than channels of conventional packaged semiconductor devices in which protocol control and interface circuitry is disposed along the outer edges of a packaged substrate, thereby reducing communication delay and/or signal loss, as well as package size, as compared to the conventional packaged semiconductor devices.

Formation of a packaged semiconductor device 460 (e.g., a device including interface or control interconnections between multiple dies) is complete after Stage 9 of FIG. 4C. In the example illustrated, the packaged semiconductor device 460 includes the first die 400, which is an example of the first die 102 of FIGS. 1-2. The packaged semiconductor device 460 also includes the second die 410, which is an example of the second die 104 of FIGS. 1-2. The packaged semiconductor device 460 also includes the interposer 438, which is an example of the interposer 108 of FIGS. 1-2. The packaged semiconductor device 460 also includes the third die 452, which is an example of the third die 202 of FIG. 2. The packaged semiconductor device 460 also includes the substrate 422, which is an example of the substrate 106 of FIGS. 1-2. The packaged semiconductor device 460 also includes the conductive pillars 434, which are an example of the electrical interconnects 138 of FIGS. 1-2.

### Exemplary Flow Diagram of a Method for Fabricating a Device Including Interface or Control Interconnections Between Multiple Dies

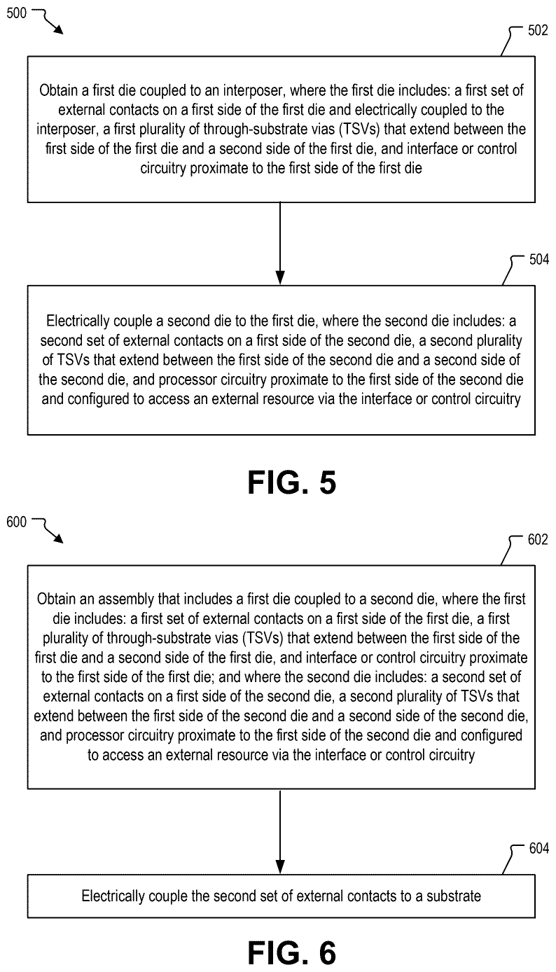

In some implementations, fabricating a device including interface or control interconnections between multiple dies includes several processes. FIG. 5 illustrates an exemplary flow diagram of a method 500 of fabricating an illustrative device that includes interface or control interconnections between multiple dies, and FIG. 6 illustrates an exemplary flow diagram of a method 600 of fabricating another exemplary device that includes interface or control interconnections between multiple dies. In a particular aspect, one or more operations of the method 500 and/or the method 600 are performed by one or more processors of a fabrication system. In some implementations, operations of the method 500 and/or the method 600 may be stored as instructions by a non-transitory computer-readable storage medium, and the instructions may be executable by at least one processor to cause the at least one processor to perform operations of the method 500 and/or the method 600, respectively. In some implementations, the method 500 of FIG. 5, the method 600 of FIG. 6, or both, may be used to provide or fabricate any of the device 100 of FIG. 1, the packaged semiconductor device 200 of FIG. 2, the packaged semiconductor device 360 of FIG. 3D, the packaged semiconductor device 390 of FIG. 3F, or the packaged semiconductor device 460 of FIG. 4C.

It should be noted that the method 500 of FIG. 5, the method 600 of FIG. 6, or both, may combine one or more processes in order to simplify and/or clarify the method for providing or fabricating an integrated circuit device. In some implementations, the order of the processes may be changed or modified.

Turning to FIG. 5, the method 500 includes obtaining a first die coupled to an interposer, at block 502. For example, Stages 3-4 of FIGS. 3A and 3B illustrate and describe examples of preparing the interposer 314 coupled to the first die 300. The first die of the method 500 can include the first die 102 of FIGS. 1-2, the first die 300 of FIGS. 3A-3F, or the first die 400 of FIGS. 4A-4C. The first die includes a first set of external contacts on a first side of the first die and electrically coupled to the interposer, a first plurality of TSVs that extend between the first side of the first die and a second side of the first die, and interface or control circuitry proximate to the first side of the first die. For example, the first set of external contacts can include or correspond to the external contacts 114 on the first side 120 of the first die 102 of FIGS. 1-2 or the external contacts 306 on the first side 302 of the first die 300 of FIGS. 3A-3F. The first plurality of TSVs may include or correspond to the first TSVs 130 of FIGS. 1-2 or the first TSVs 307 of FIGS. 3A-3F, and the interface or control circuitry may include or correspond to the interface or control circuitry 110 of FIGS. 1-2 or the interface or control circuitry 308 of FIGS. 3A-3F.

The method 500 includes electrically coupling a second die to the first die, at block 504. For example, Stage 6 of FIG. 3B illustrates and describes examples of coupling the second die 330 to the first die 300. The second die of the method 500 can include the second die 104 of FIGS. 1-2 or the second die 330 of FIGS. 3A-3F. The second die includes a second set of external contacts on a first side of the second die, a second plurality of TSVs that extend between the first side of the second die and a second side of the second die, and processor circuitry proximate to the first side of the second die and configured to access an external resource via the interface or control circuitry. For example, the second set of external contacts can include or correspond to the external contacts 116 on the first side 124 of the second die 104 of FIGS. 1-2 or the external contacts 336 on the first side 332 of the second die 330 of FIGS. 3A-3F. The second plurality of TSVs may include or correspond to the second TSVs 132 of FIGS. 1-2 or the second TSVs 337 of FIGS. 3A-3F, and the processor circuitry may include or correspond to the processor circuitry 112 of FIGS. 1-2 or the processor circuitry 338 of FIGS. 3A-3F.

In some implementations, electrically coupling the second die to the first die includes forming joints between the first plurality of TSVs and the second plurality of TSVs using micro-bump bonding or hybrid bonding. For example, the joints may include or correspond to the joints 118 of FIGS. 1-2 or the joints 339 of FIGS. 3A-3F. Signal paths between the second die and the first die include corresponding TSVs of the second plurality of TSVs and corresponding TSVs of the first plurality of TSVs. For example, the signal path 208 of FIG. 2 may include corresponding TSVs of the first TSVs 130 and the second TSVs 132.

In some implementations, the method 500 also includes, prior to electrically coupling the second die to the first die, attaching the first die to a carrier structure and applying mold compound to at least partially encapsulate the first die. For example, Stage 2 of FIG. 3A illustrates and describes examples of coupling the first die 300 to the carrier structure 310, and Stage 3 of FIG. 3A illustrates and describes examples of applying the mold compound 312 to at least partially encapsulate the first die 300. The carrier structure may include or correspond to the carrier structure 310 of FIGS. 3A-3F, and the mold compound may include or correspond to the mold compound 140 of FIGS. 1-2 or the mold compound 312 of FIGS. 3A-3F. The method 500 also includes forming a first set of redistribution layers on the first side of the first die and the mold compound and separating the first die from the carrier structure. In such implementations, the interposer includes the first set of redistribution layers. For example, Stage 3 of FIG. 3A illustrates and describes examples of forming the redistribution layers 316 on the first die 300 and the mold compound 312, as well as separating the carrier structure 310 from the first die 300. The first set of redistribution layers may include or correspond to the redistribution layers 142 of FIGS. 1-2 or the redistribution layers 316 of FIGS. 3A-3F. In some such implementations, the method 500 also includes forming a plurality of cavities within the mold compound, forming a plurality of electrical interconnects at least partially within the plurality of cavities, and applying the mold compound to at least partially encapsulate the second die and the plurality of electrical interconnects. For example, Stage 7 of FIG. 3C illustrates and describes examples of forming the electrical interconnects 340 within cavities of the mold compound 312, and Stage 8 of FIG. 3C illustrates and describes examples of applying the mold compound 312 to at least partially encapsulate the second die 330 and the electrical interconnects 340. The plurality of electrical interconnects may include or correspond to the electrical interconnects 138 of FIGS. 1-2 or the electrical interconnects 340 of FIGS. 3A-3F.

In some implementations in which the mold compound is applied, the method 500 includes forming a second set of redistribution layers on the second side of the second die and the mold compound and forming a second set of off-package contacts on a second side of the substrate that is opposite to the first side of the substrate. For example, Stage 9 of FIG. 3D illustrates and describes examples of forming the redistribution layers 343 and the off-package contacts 350 on the second side 346 of the substrate 342 (which includes or corresponds to the redistribution layers 343). The second set of redistribution layers may include or correspond to the layers of one or more embodiments of the substrate 106 of FIGS. 1-2 or the redistribution layers 343 of FIGS. 3A-3F, and the second set of off-package contacts may include or correspond to the off-package contacts 154 of FIGS. 1-2 or the off-package contacts 350 of FIGS. 3A-3F. The second set of redistribution layers includes or corresponds to a substrate having a first side that is electrically coupled to the second set of external contacts. For example, the substrate includes or corresponds to the substrate 106 of FIGS. 1-2 or the substrate 342 of FIGS. 3A-3F. In some such implementations, the method 500 also includes electrically coupling the external resource to the first set of off-package contacts. For example, Stage 11 of FIG. 3D illustrates and describes examples of electrically coupling the third die 354 to the off-package contacts 324 of the interposer 314. The external resource may include or correspond to the third die 202 of FIG. 2 or the third die 354 of FIGS. 3A-3F.

In some implementations in which the mold compound is applied, the method 500 includes forming a set of conductive connectors on the plurality of electrical interconnects and the second set of external contacts, electrically coupling a first side of a laminate substrate to the set of conductive connectors, and forming a second set of off-package contacts on a second side of the laminate substrate that is opposite to the first side of the laminate substrate. For example, Stage 12 of FIG. 3E illustrates and describes examples of forming the conductive connectors 370, and Stage 13 of FIG. 3E illustrates and describes examples of electrically coupling the first side 374 of the substrate 372 to the conductive connectors 370 and forming the off-package contacts 380 on the second side 376 of the substrate 372. The conductive connectors may include or correspond to the conductive connectors 370 of FIGS. 3A-3F, the laminate substrate may include or correspond to the substrate 106 of FIGS. 1-2 or the substrate 372 of FIGS. 3A-3F, and the second set of off-package contacts may include or correspond to the off-package contacts 154 of FIGS. 1-2 or the off-package contacts 380 of FIGS. 3A-3F. In some such implementations, the set of conductive connectors are solder bumps or metal posts. Additionally, or alternatively, the method 500 may also include electrically coupling the external resource to the first set of off-package contacts. For example, Stage 15 of FIG. 3F illustrates and describes examples of coupling the third die 384 to the off-package contacts 324 of the interposer 314. The external resource may include or correspond to the third die 202 of FIGS. 1-2 or the third die 384 of FIGS. 3A-3F.

Turning to FIG. 6, the method 600 includes obtaining an assembly that includes a first die coupled to a second die, at block 602. For example, Stage 1 of FIG. 4A illustrates and describes examples of obtaining the assembly 401 that includes the first die 400 coupled to the second die 410. The first die of the method 600 can include the first die 102 of FIGS. 1-2 or the first die 400 of FIGS. 4A-4C, and the second die of the method 600 can include the second die 104 of FIGS. 1-2 or the second die 410 of FIGS. 4A-4C.

The first die includes a first set of external contacts on a first side of the first die, a first plurality of TSVs that extend between the first side of the first die and a second side of the first die, and interface or control circuitry proximate to the first side of the first die. For example, the first set of external contacts can include or correspond to the external contacts 114 on the first side 120 of the first die 102 of FIGS. 1-2 or the external contacts 406 on the first side 402 of the first die 400 of FIGS. 4A-4C. The first plurality of TSVs may include or correspond to the first TSVs 130 of FIGS. 1-2 or the first TSVs 407 of FIGS. 4A-4C, and the interface or control circuitry may include or correspond to the interface or control circuitry 110 of FIGS. 1-2 or the interface or control circuitry 408 of FIGS. 4A-4C.

The second die includes a second set of external contacts on a first side of the second die, a second plurality of TSVs that extend between the first side of the second die and a second side of the second die, and processor circuitry proximate to the first side of the second die and configured to access an external resource via the interface or control circuitry. For example, the second set of external contacts can include or correspond to the external contacts 116 on the first side 124 of the second die 104 of FIGS. 1-2 or the external contacts 416 on the first side 412 of the second die 410 of FIGS. 4A-4C. The second plurality of TSVs may include or correspond to the second TSVs 132 of FIGS. 1-2 or the second TSVs 417 of FIGS. 4A-4C, and the processor circuitry may include or correspond to the processor circuitry 112 of FIGS. 1-2 or the processor circuitry 418 of FIGS. 4A-4C.

The method 600 includes electrically coupling the second set of external contacts to a substrate, at block 604. For example, Stage 4 of FIG. 4B illustrates and describes examples of electrically coupling the external contacts 416 to the substrate 422. The substrate of the method 600 can include the substrate 106 of FIGS. 1-2 or the substrate 422 of FIGS. 4A-4C.

In some implementations, the method 600 also includes, prior to electrically coupling the second die to the substrate, coupling a set of conductive pillars to a first side of the substrate. The second die is electrically coupled to the first side of the substrate. For example, Stage 3 of FIG. 4A illustrates and describes examples of coupling the conductive pillars 434 to the first side 424 of the substrate 422. The conductive pillars may include or correspond to the electrical interconnects 138 of FIGS. 1-2 or the conductive pillars 434 of FIGS. 4A-4C. In such implementations, the method 600 also includes applying a mold compound to at least partially encapsulate the first die, the second die, the set of conductive pillars, and the substrate. For example, Stage 5 of FIG. 4B illustrates and describes examples of applying the mold compound 436 to at least partially encapsulate the first die 400, the second die 410, the conductive pillars 434, and the substrate 422. The mold compound may include or correspond to the mold compound 140 of FIGS. 1-2 or the mold compound 436 of FIGS. 4A-4C.

In some implementations that include electrically coupling the second die to the substrate and applying the mold compound, the method 600 also includes forming a first set of redistribution layers on the first die, the mold compound, and the set of conductive pillars. The first set of redistribution layers includes an interposer having a first side that is electrically coupled to the first set of external contacts. For example, Stage 6 of FIG. 4B illustrates and describes examples of forming the redistribution layers 448. The first set of redistribution layers may include or correspond to the redistribution layers 142 of FIGS. 1-2 or the redistribution layers 448 of FIGS. 4A-4C. The interposer may include or correspond to the interposer 108 of FIGS. 1-2 or the interposer 438 of FIGS. 4A-4C. In such examples, the method 600 also includes forming a first set of off-package contacts on a second side of the interposer that is opposite from the first side of the interposer and forming a second set of off-package contacts on a second side of the substrate that is opposite from the first side of the substrate. For example, Stage 6 of FIG. 4B illustrates and describes examples of forming the on-package contacts 444 on the first side 440 of the interposer 438 and forming the off-package contacts 446 on the second side 442 of the interposer 438. The first set of off-package contacts may include or correspond to the off-package contacts 144 of the interposer 108 of FIGS. 1-2 or the off-package contacts 446 of the interposer 438 of FIGS. 4A-4C, and the second set of off-package contacts may include or correspond to the off-package contacts 154 of the substrate 106 of FIGS. 1-2 or the off-package contacts 430 of the substrate 422 of FIGS. 4A-4C. The substrate may include a second set of redistribution layers or a laminate substrate. In some such examples, the method 600 also includes electrically coupling the external resource to the first set of off-package contacts. For example, Stage 9 of FIG. 4C illustrates and describes examples of electrically coupling the third die 452 to the off-package contacts 446 of the interposer 438. The external resource may include or correspond to the third die 202 of FIG. 2 or the third die 452 of FIGS. 4A-4C.

### Exemplary Electronic Devices

FIG. 7 illustrates various electronic devices that may include or be integrated with any of the device 100 (that includes the interface or control interconnections between multiple dies), the packaged semiconductor device 200, the packaged semiconductor device 360, the packaged semiconductor device 390, or the packaged semiconductor device 460. For example, a mobile phone device 702, a laptop computer device 704, a fixed location terminal device 706, a wearable device 708, or a vehicle 710 (e.g., an automobile or an aerial device) may include a device 700. The device 700 can include, for example, any of the device 100, the packaged semiconductor device 200, the packaged semiconductor device 360, the packaged semiconductor device 390, the packaged semiconductor device 460, and/or any other integrated device that includes a conductive structure described herein. The devices 702, 704, 706 and 708 and the vehicle 710 illustrated in FIG. 7 are merely exemplary. Other electronic devices may also feature the device 700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-7 may be rearranged and/or combined into a single component, process, feature or function or embodied in several components, processes, or functions. Additional elements, components, processes, and/or functions may also be added without departing from the disclosure. It should also be noted FIGS. 1-7 and its corresponding description in the present disclosure is not limited to dies and/or ICs. In some implementations, FIGS. 1-7 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.
According to Example 1, a device includes a first die and a second die. The first die includes: a first set of external contacts on a first side of the first die; a first plurality of through-substrate vias (TSVs) that extend between the first side of the first die and a second side of the first die; and interface or control circuitry proximate to the first side of the first die. The second die includes: a second set of external contacts on a first side of the second die; a second plurality of TSVs that extend between the first side of the second die and a second side of the second die; and processor circuitry proximate to the first side of the second die and configured to access an external resource via the interface or control circuitry.
Example 2 includes the device of Example 1, where the second side of the first die is electrically coupled to the second side of the second die, and wherein the first plurality of TSVs and the second plurality of TSVs are arranged to form a plurality of interconnected TSV pairs that extend between the first side of the first die and the first side of the second die.
Example 3 includes the device of Example 1 or Example 2, and further includes: an interposer that includes a first set of on-package contacts, wherein a portion of the first set of on-package contacts is electrically coupled to the first set of external contacts; a substrate that includes a second set of on-package contacts, wherein a portion of the second set of on-package contacts is electrically coupled to the second set of external contacts; and mold compound that at least partially encapsulates the first die, the second die, the substrate, and the interposer.
Example 4 includes the device of Example 3, and further includes a set of electrical interconnects between the substrate and the interposer, wherein the set of electrical interconnects are disposed within the mold compound and at least partially surround the first die and the second die.
Example 5 includes the device of Example 3 or Example 4, where the first set of on-package contacts are on a first side of the interposer, and wherein the interposer comprises: a set of redistribution layers; and a first set of off-package contacts on a second side of the interposer that is opposite from the first side of the interposer.
Example 6 includes the device of Example 5, and further includes the external resource that is electrically coupled to the first set of off-package contacts, wherein the external resource comprises a dynamic random-access memory (DRAM) die, and wherein the interface or control circuitry comprises DRAM protocol control circuitry.
Example 7 includes the device of Example 3, wherein the second set of on-package contacts are on a first side of the substrate, and wherein the substrate comprises: one or more redistribution layers; and a second set of off-package contacts on a second side of the substrate that is opposite from the first side of the substrate.
Example 8 includes the device of Example 3, wherein the second set of on-package contacts are on a first side of the substrate, and wherein the substrate comprises: a laminate substrate; and a second set of off-package contacts on a second side of the substrate that is opposite from the first side of the substrate.
According to Example 9, a method of semiconductor fabrication includes: obtaining a first die coupled to an interposer, wherein the first die includes: a first set of external contacts on a first side of the first die and electrically coupled to the interposer; a first plurality of through-substrate vias (TSVs) that extend between the first side of the first die and a second side of the first die; and interface or control circuitry proximate to the first side of the first die; and the method also includes: electrically coupling a second die to the first die, wherein the second die includes: a second set of external contacts on a first side of the second die; a second plurality of TSVs that extend between the first side of the second die and a second side of the second die; and processor circuitry proximate to the first side of the second die and configured to access an external resource via the interface or control circuitry.
Example 10 includes the method of Example 9, where said electrically coupling the second die to the first die comprises: forming joints between the first plurality of TSVs and the second plurality of TSVs using micro-bump bonding or hybrid bonding, wherein signal paths between the second die and the first die include corresponding TSVs of the second plurality of TSVs and corresponding TSVs of the first plurality of TSVs.
Example 11 includes the method of Example 9 or Example 10, and further includes, prior to said electrically coupling the second die to the first die: attaching the first die to a carrier structure; applying mold compound to at least partially encapsulate the first die; forming a first set of redistribution layers on the first side of the first die and the mold compound, wherein the interposer comprises the first set of redistribution layers; and separating the first die from the carrier structure.
Example 12 includes the method of Example 11, and further includes: forming a plurality of cavities within the mold compound; forming a plurality of electrical interconnects at least partially within the plurality of cavities; and applying the mold compound to at least partially encapsulate the second die and the plurality of electrical interconnects.
Example 13 includes the method of Example 12, where the interposer includes a first set of off-package contacts, and the method further includes: forming a second set of redistribution layers on the second side of the second die and the mold compound, wherein the second set of redistribution layers comprises a substrate having a first side that is electrically coupled to the second set of external contacts; and forming a second set of off-package contacts on a second side of the substrate that is opposite to the first side of the substrate.
Example 14 includes the method of Example 13, and further includes electrically coupling the external resource to the first set of off-package contacts.
Example 15 includes the method of Example 12, where the interposer includes a first set of off-package contacts, and the method further includes: forming a set of conductive connectors on the plurality of electrical interconnects and the second set of external contacts; electrically coupling a first side of a laminate substrate to the set of conductive connectors; and forming a second set of off-package contacts on a second side of the laminate substrate that is opposite to the first side of the laminate substrate.
Example 16 includes the method of Example 15, where the set of conductive connectors comprise solder bumps or metal posts.
Example 17 includes the method of Example 15 or Example 16, and further includes electrically coupling the external resource to the first set of off-package contacts.
According to Example 18 a method of semiconductor fabrication includes: obtaining an assembly that includes a first die coupled to a second die, wherein the first die includes: a first set of external contacts on a first side of the first die; a first plurality of through-substrate vias (TSVs) that extend between the first side of the first die and a second side of the first die; and interface or control circuitry proximate to the first side of the first die, and wherein the second die includes: a second set of external contacts on a first side of the second die; a second plurality of TSVs that extend between the first side of the second die and a second side of the second die; and processor circuitry proximate to the first side of the second die and configured to access an external resource via the interface or control circuitry; and the method also includes: electrically coupling the second set of external contacts to a substrate.
Example 19 includes the method of Example 18, and further includes, prior to said electrically coupling the second die to the substrate: coupling a set of conductive pillars to a first side of the substrate, wherein the second die is electrically coupled to the first side of the substrate; and applying a mold compound to at least partially encapsulate the first die, the second die, the set of conductive pillars, and the substrate.
Example 20 includes the method of Example 19, and further includes: forming a first set of redistribution layers on the first die, the mold compound, and the set of conductive pillars, wherein the first set of redistribution layers comprises an interposer having a first side that is electrically coupled to the first set of external contacts; forming a first set of off-package contacts on a second side of the interposer that is opposite from the first side of the interposer; and forming a second set of off-package contacts on a second side of the substrate that is opposite from the first side of the substrate.
Example 21 includes the method of Example 20, and further includes electrically coupling the external resource to the first set of off-package contacts.
Example 22 includes the method of Example 20 or Example 21, where the substrate comprises a second set of redistribution layers.
Example 23 includes the method of Example 20 or Example 21, where the substrate comprises a laminate substrate.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a first die including:
a first set of external contacts on a first side of the first die;
a first plurality of through-substrate vias (TSVs) that extend between the first side of the first die and a second side of the first die; and
interface or control circuitry proximate to the first side of the first die; and
a second die including:
a second set of external contacts on a first side of the second die;
a second plurality of TSVs that extend between the first side of the second die and a second side of the second die; and
processor circuitry proximate to the first side of the second die and configured to access an external resource via the interface or control circuitry.

2. The device of claim 1, wherein the second side of the first die is electrically coupled to the second side of the second die, and wherein the first plurality of TSVs and the second plurality of TSVs are arranged to form a plurality of interconnected TSV pairs that extend between the first side of the first die and the first side of the second die.

3. The device of claim 1, further comprising:
an interposer that includes a first set of on-package contacts, wherein a portion of the first set of on-package contacts is electrically coupled to the first set of external contacts;
a substrate that includes a second set of on-package contacts, wherein a portion of the second set of on-package contacts is electrically coupled to the second set of external contacts; and
mold compound that at least partially encapsulates the first die, the second die, the substrate, and the interposer.

4. The device of claim 3, further comprising:
a set of electrical interconnects between the substrate and the interposer, wherein the set of electrical interconnects are disposed within the mold compound and at least partially surround the first die and the second die.

5. The device of claim 3, wherein the first set of on-package contacts are on a first side of the interposer, and wherein the interposer comprises:
a set of redistribution layers; and
a first set of off-package contacts on a second side of the interposer that is opposite from the first side of the interposer.

6. The device of claim 5, further comprising:
the external resource that is electrically coupled to the first set of off-package contacts, wherein the external resource comprises a dynamic random-access memory (DRAM) die, and wherein the interface or control circuitry comprises DRAM protocol control circuitry.

7. The device of claim 3, wherein the second set of on-package contacts are on a first side of the substrate, and wherein the substrate comprises:
one or more redistribution layers; and
a second set of off-package contacts on a second side of the substrate that is opposite from the first side of the substrate.

8. The device of claim 3, wherein the second set of on-package contacts are on a first side of the substrate, and wherein the substrate comprises:
a laminate substrate; and
a second set of off-package contacts on a second side of the substrate that is opposite from the first side of the substrate.

9. A method comprising:
obtaining a first die coupled to an interposer, wherein the first die includes:
a first set of external contacts on a first side of the first die and electrically coupled to the interposer;
a first plurality of through-substrate vias (TSVs) that extend between the first side of the first die and a second side of the first die; and
interface or control circuitry proximate to the first side of the first die; and
electrically coupling a second die to the first die, wherein the second die includes:
a second set of external contacts on a first side of the second die;
a second plurality of TSVs that extend between the first side of the second die and a second side of the second die; and
processor circuitry proximate to the first side of the second die and configured to access an external resource via the interface or control circuitry.

10. The method of claim 9, wherein said electrically coupling the second die to the first die comprises:
forming joints between the first plurality of TSVs and the second plurality of TSVs using micro-bump bonding or hybrid bonding, wherein signal paths between the second die and the first die include corresponding TSVs of the second plurality of TSVs and corresponding TSVs of the first plurality of TSVs.

11. The method of claim 9, further comprising, prior to said electrically coupling the second die to the first die:
attaching the first die to a carrier structure;
applying mold compound to at least partially encapsulate the first die;
forming a first set of redistribution layers on the first side of the first die and the mold compound, wherein the interposer comprises the first set of redistribution layers; and
separating the first die from the carrier structure.

12. The method of claim 11, further comprising:
forming a plurality of cavities within the mold compound;
forming a plurality of electrical interconnects at least partially within the plurality of cavities; and
applying the mold compound to at least partially encapsulate the second die and the plurality of electrical interconnects.

13. The method of claim 12, wherein the interposer includes a first set of off-package contacts, and further comprising:
forming a second set of redistribution layers on the second side of the second die and the mold compound, wherein the second set of redistribution layers comprises a substrate having a first side that is electrically coupled to the second set of external contacts; and
forming a second set of off-package contacts on a second side of the substrate that is opposite to the first side of the substrate.

14. The method of claim 13, further comprising:
electrically coupling the external resource to the first set of off-package contacts.

15. The method of claim 12, wherein the interposer includes a first set of off-package contacts, and further comprising:
forming a set of conductive connectors on the plurality of electrical interconnects and the second set of external contacts;
electrically coupling a first side of a laminate substrate to the set of conductive connectors; and
forming a second set of off-package contacts on a second side of the laminate substrate that is opposite to the first side of the laminate substrate.

16. The method of claim 15, wherein the set of conductive connectors comprise solder bumps or metal posts.

17. The method of claim 15, further comprising:
electrically coupling the external resource to the first set of off-package contacts.

18. A method comprising:
obtaining an assembly that includes a first die coupled to a second die,
wherein the first die includes:
a first set of external contacts on a first side of the first die;
a first plurality of through-substrate vias (TSVs) that extend between the first side of the first die and a second side of the first die; and
interface or control circuitry proximate to the first side of the first die, and
wherein the second die includes:
a second set of external contacts on a first side of the second die;
a second plurality of TSVs that extend between the first side of the second die and a second side of the second die; and
processor circuitry proximate to the first side of the second die and configured to access an external resource via the interface or control circuitry; and
electrically coupling the second set of external contacts to a substrate.

19. The method of claim 18, further comprising:
prior to said electrically coupling the second die to the substrate, coupling a set of conductive pillars to a first side of the substrate, wherein the second die is electrically coupled to the first side of the substrate; and
applying a mold compound to at least partially encapsulate the first die, the second die, the set of conductive pillars, and the substrate.

20. The method of claim 19, further comprising:
forming a first set of redistribution layers on the first die, the mold compound, and the set of conductive pillars, wherein the first set of redistribution layers comprises an interposer having a first side that is electrically coupled to the first set of external contacts;
forming a first set of off-package contacts on a second side of the interposer that is opposite from the first side of the interposer; and
forming a second set of off-package contacts on a second side of the substrate that is opposite from the first side of the substrate.
